(19) United States
(12) Patent Application Publication
(10) Pub. No.: US 2023/0317546 A1
(43) Pub. Date: Oct. 5, 2023

(54) DIE BACKSIDE FILM WITH OVERHANG FOR DIE SIDEWALL PROTECTION

(71) Applicant: Intel Corporation, Santa Clara, CA (US)

(72) Inventors: Xavier Brun, Hillsboro, OR (US); Nabankur Deb, Hillsboro, OR (US); Feras Eid, Chandler, AZ (US)

(73) Assignee: Intel Corporation, Santa Clara, CA (US)

(21) Appl. No.: 17/710,670

(22) Filed: Mar. 31, 2022

(51) Int. Cl. H01L 23/367; H01L 21/78

(52) U.S. Cl. CPC H01L 23/367; H01L 21/78; H01L 23/3135

(57) ABSTRACT

Embodiments are directed to a device having an overhang portion. In some embodiments, a main body structure of the device comprises an IC die and an exterior surface of the main body structure comprises the overhang portion. The overhang portion adjoins a sidewall structure of the main body structure of the device, which is substantially perpendicular to a backside of the IC die. In some embodiments, the main body structure further comprises a package mold structure, which comprises the overhang portion.

### BACKGROUND

### 1. Technical Field

Embodiments generally relate to integrated circuit (IC) dies and more particularly, but not exclusively, to assembling one or more IC dies into an IC package.

### 2. Background Art

Devices comprising electronic circuitry may be fabricated on a wafer of semiconductor material. Each device typically contains multiple layers. A layer may contain, for example, circuit components, such as transistors, electrical interconnect structures, dielectric materials, or a combination of the foregoing. After the devices are fabricated, the wafer is singulated, i.e., cut, into numerous individual IC dies. To protect the die, it may be partially or completely enclosed in an IC package. A package may include a single die or multiple dies. Once assembled, the IC package may be integrated into a computer or other electronic system. There are many challenges with assembling one or multiple IC dies into an IC package.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1A is a simplified cross-sectional side view of a device comprising an IC die having an overhang portion in accordance with various embodiments. FIGS. 1B-D are simplified cross-sectional side views of the overhang portion of FIG. 1A in accordance with various embodiments. FIG. 1E is a cross-sectional plan view of the device of FIG. 1A in accordance with various embodiments.

FIG. 2 illustrates a flow diagram of a method for fabricating an IC package having an overhang portion according to some embodiments.

FIG. 3A is a simplified cross-sectional side view of a device comprising a monolithic die that includes an overhang portion according to various embodiments. FIG. 3B is a simplified cross-sectional side view of the overhang portion of FIG. 3A according to some embodiments.

FIG. 4A is a simplified cross-sectional side view of a device comprising a mold structure around an IC die, wherein the mold structure comprises an overhang portion, according to various embodiments. FIG. 4B is a simplified cross-sectional side view of the overhang portion of FIG. 4A according to some embodiments.

FIG. 5A is a simplified cross-sectional side view of a device comprising a mold structure around multiple IC dies, wherein the mold structure comprises an overhang portion, according to various embodiments. FIG. 5B is a simplified cross-sectional side view of the overhang portion of FIG. 5A according to some embodiments.

FIG. 6A is a top plan view of a microelectronic device wafer to which embodiments of a two-step singulation process may be applied according to various embodiments. FIG. 6B is a side cross-sectional view of a portion of the microelectronic device wafer of FIG. 6A according to various embodiments.

FIGS. 7A through 7E are simplified cross-sectional side view diagrams, each illustrating respective stages of a process to form an IC package containing a single IC die according to various embodiments.

FIGS. 8A through 8B are simplified cross-sectional side view diagrams illustrating a portion of the microelectronic device wafer of FIG. 6A undergoing a two-step singulation process according to various embodiments.

FIG. 9A is a top plan view of a microelectronic device wafer having multiple IC dies disposed thereon, according to various embodiments. FIG. 9B is a side cross-sectional view of the microelectronic device wafer of FIG. 9A according to various embodiments.

FIGS. 10A through 10G are simplified cross-sectional side view diagrams, each illustrating respective stages of a process to form an IC package containing two IC dies according to an embodiment.

FIG. 11A is a simplified cross-sectional side view of a device comprising a mold structure around multiple IC dies in a side-by-side arrangement, wherein the mold structure comprises an overhang portion, according to various embodiments. FIG. 11B is a cross-sectional side view of the overhang portion of the package mold structure of FIG. 11A according to some embodiments.

FIG. 12 illustrates a mobile computing platform and a data server machine employing an IC package, in accordance with some embodiments.

FIG. 13 is a functional block diagram of an electronic computing device, in accordance with some embodiments.

### DETAILED DESCRIPTION

There are many challenges with assembling one or more IC dies into an IC package. IC dies generate heat and one challenge can be keeping the die below a specified temperature limit during operation. Metals have better thermal conductivity compared to silicon or mold compound materials used in an IC package. Depositing a metal die backside film (DBF) on a silicon die or on a mold compound can improve thermal performance Since DBFs are typically metal, they tend to be ductile. In contrast, silicon and mold tend to be brittle. While the use of a metal DBF improves the ability of the IC package to operate within specified temperature limits, the difference in material properties between die or mold material and DBF material can make it difficult to singulate the die.

Underfill material (UF) can be used in an IC package. In addition to challenges associated with singulation, ensuring that underfill material adheres to all of the package components that it contacts can be an issue. Adhesion of underfill material to metal can be poor. Poor adhesion of UF to a DBF can lead to delamination of the UF where the UF and DBF interface.

Another challenge can arise from the rectilinear geometry of an IC die. A die is commonly a rectangular cuboid having a front side, back side, and four sidewalls. Because the side walls are substantially flat, stress can occur in the material where a sidewall and a DBF meet. The flat edge shape of the die sidewall can make the sidewall prone to cracking and susceptible to chipping during downstream manufacturing processes. Cracking and chipping may lead to long term performance and reliability concerns.

As further described below, embodiments are directed to an overhang portion. In some embodiments, a main body structure comprises an IC die and an exterior surface of the main body structure comprises the overhang portion. In some embodiments, the main body structure further comprises a package mold structure, which comprises the overhang portion.

In some embodiments, devices comprise a main body structure and a film on the main body structure. The film is comprised of a thermal dissipation material. The main body structure comprises an IC die having an exterior surface. The exterior surface of the IC die includes a backside, a sidewall structure, and an overhang portion. The sidewall structure is substantially perpendicular to the backside of the IC die. The overhang portion adjoins the sidewall structure. The film extends along the overhang portion.

In some embodiments, the sidewall structure is a first sidewall structure, and the overhang portion further comprises a second sidewall structure. In these embodiments, the second sidewall structure is substantially perpendicular to the backside of the IC die. In some embodiments, the IC die comprises the sidewall structure and the overhang portion.

In some embodiments, the sidewall structure is a first sidewall structure and the overhang portion is a first overhang portion. In these embodiments, the device further comprises a package mold structure which extends around the main body structure. An exterior surface of the package mold structure comprises a second sidewall structure which is substantially perpendicular to the backside of the IC die. An overhang portion of the package mold structure adjoins the second sidewall structure.

In some embodiments, the main body structure further comprises a package mold which extends around the IC die. The package mold comprises the sidewall structure and the overhang portion.

An advantage of various embodiments is that the overhang portion structure may eliminate a stress concentration region in the IC die and protect the die sidewall region beneath the overhang portion, thereby protecting the sidewall from die breakage, chipping, and other defects in downstream processes. An additional advantage is that the overhang portion may help contain underfill and thereby improve its adhesion to the sidewall. Improved adhesion may prevent underfill delamination from the die sidewalls and prevent underfill contamination on a top side of the die. A further advantage may result from use of a two-step singulation process. In one step, one or more brittle layers, such as layers formed from silicon or mold, are singulated. In another step, ductile layers, such as a metal DBF, are singulated. Use of a two-step singulation process can account for differences in material properties between die or mold material and DBF material. The two-step singulation process may produce more successful cuts in silicon dies or mold materials in IC dies having a metal DBF than might be achieved with a single step singulation process.

Embodiments are described with reference to the enclosed figures. While specific configurations and arrangements are depicted and discussed in detail, it should be understood that this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that embodiments may be practiced without these specific details. In some instances, well-known methods and devices are shown in block diagram form, rather than in detail, to avoid obscuring the embodiments. Reference throughout this specification to “an embodiment” or “one embodiment” or “some embodiments” means that a particular feature, structure, function, or characteristic described in connection with the embodiment is included in at least one embodiment. Thus, the appearances of the phrase “in an embodiment” or “in one embodiment” or “some embodiments” in various places throughout this specification are not necessarily referring to the same embodiment. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. It should be understood that these terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause and effect relationship).

The terms “over,” “under,” “between,” and “on” as used herein refer to a relative position of one component or material with respect to other components or materials where such physical relationships are noteworthy. For example, in the context of materials, one material or layer over or under another may be directly in contact or may have one or more intervening materials or layers. Moreover, one material between two materials or layers may be directly in contact with the two materials/layers or may have one or more intervening materials/layers. In contrast, a first material or layer “on” a second material or layer is in direct physical contact with that second material/layer. Similar distinctions are to be made in the context of component assemblies.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

Unless otherwise specified in the specific context of use, the term “predominantly” means more than 50%, or more than half. For example, a composition that is predominantly a first constituent means more than half of the composition is the first constituent (e.g., <50 at. %). The term “primarily” means the most, or greatest, part. For example, a composition that is primarily a first constituent means the composition has more of the first constituent than any other constituent. A composition that is primarily first and second constituents means the composition has more of the first and second constituents than any other constituent. The term “substantially” means there is only incidental variation. For example, composition that is substantially a first constituent means the composition may further include <1% of any other constituent. A composition that is substantially first and second constituents means the composition may further include <1% of any constituent substituted for either the first or second constituent.

The term “package” generally refers to a self-contained carrier of one or more dice, where the dice are attached to the package substrate, and may be encapsulated for protection, with integrated or wire-bonded interconnects between the dice and leads, pins or bumps located on the external portions of the package substrate. The package may contain a single die, or multiple dies, providing a specific function. The package is usually mounted on a printed circuit board for interconnection with other packaged integrated circuits and discrete components, forming a larger circuit.

The term “dielectric” generally refers to any number of non-electrically conductive materials that make up the structure of a package substrate. For purposes of this disclosure, dielectric material may be incorporated into an integrated circuit package as layers of laminate film or as a resin molded over integrated circuit dice mounted on the substrate.

The term “metallization” generally refers to metal layers formed over and through the dielectric material of the package substrate. The metal layers are generally patterned to form metal structures such as traces and bond pads. The metallization of a package substrate may be confined to a single layer or in multiple layers separated by layers of dielectric.

The term “bond pad” generally refers to metallization structures that terminate integrated traces and vias in integrated circuit packages and dies. The term “solder pad” may be occasionally substituted for “bond pad” and carries the same meaning. In addition, the term “conductive contact” may be used for “bond pad” and carries the same meaning.

The term “solder bump” generally refers to a solder layer formed on a bond pad. The solder layer typically has a round shape, hence the term “solder bump”.

In this description and the claims, the terms “conductive contact” and “metal feature” have the same meaning. In this description and the claims, the term “interconnect structure” may refer to a “conductive pillar” or other interconnect structure.

The term “substrate” generally refers to a planar platform comprising dielectric and metallization structures. The substrate mechanically supports and electrically couples one or more IC dies on a single platform, with encapsulation of the one or more IC dies by a moldable dielectric material. The substrate generally comprises solder bumps as bonding interconnects on both sides. One side of the substrate, generally referred to as the “die side”, comprises solder bumps for chip or die bonding. The opposite side of the substrate, generally referred to as the “land side”, comprises solder bumps for bonding the package to a printed circuit board.

The vertical orientation is in the z-direction and it is understood that recitations of “top,” “bottom,” “above,” and “below” refer to relative positions in the z-dimension with the usual meaning. However, it is understood that embodiments are not necessarily limited to the orientations or configurations illustrated in the figure.

Views labeled “cross-sectional,” “profile,” and “plan” correspond to orthogonal planes within a cartesian coordinate system. Thus, cross-sectional and profile views are taken in the x-z plane, and plan views are taken in the x-y plane. Typically, profile views in the x-z plane are cross-sectional views. Where appropriate, drawings are labeled with axes to indicate the orientation of the figure.

The IC package examples described herein may be manufactured, in part, with bonding techniques in which metal features embedded within an insulator of a top-side IC die are directly fused to metal features embedded within an insulator of a bottom-side die. Where both the metal features and the insulators are fused, the resultant composite structure comprises a hybrid bonded interface of both metallurgically interdiffused metals and chemically bonded insulators. Prior to bonding, each top-side IC die may be fabricated in a monolithic process separate from that of each bottom-side die. As such, each top-side IC die may utilize the same or different semiconductor device fabrication technologies as the bottom-side die bonded to the top-side die. Likewise, prior to assembly, the bottom-side die may be fabricated according a monolithic process separate from that of the top-side IC die.

Direct bonding, may also be referred to in this description and in the claims as hybrid bonding. As described above, direct bonding refers to a first IC die attached to a second IC die via bonds formed between both metallization features of the first IC die and the second IC die (e.g., via metal interdiffusion) and between dielectric materials of the first IC die and a second IC die.

As used herein, the term “hardware interface” refers to one or more physical components of a given device, where said one or more physical components accommodate coupling to interact with one or more physical components of another device. For example, a hardware interface may comprise metal contacts, pads, metallization features, or other interconnect structures on a surface of or within a circuit board or integrated circuit (IC) chip. As another example, a hardware interface may comprise an interconnect between contacts of respective components, such as solder or an interposer.

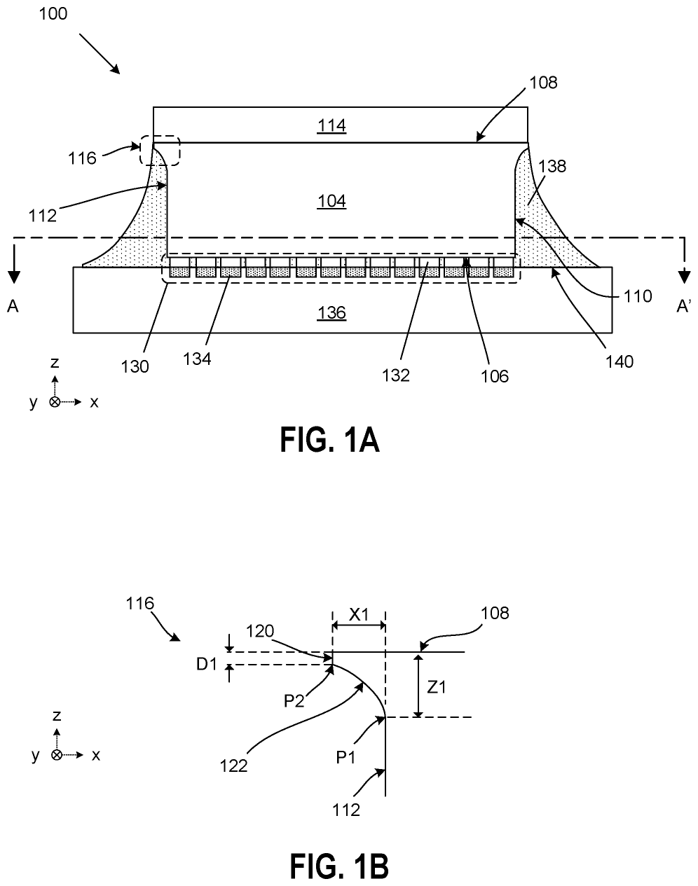

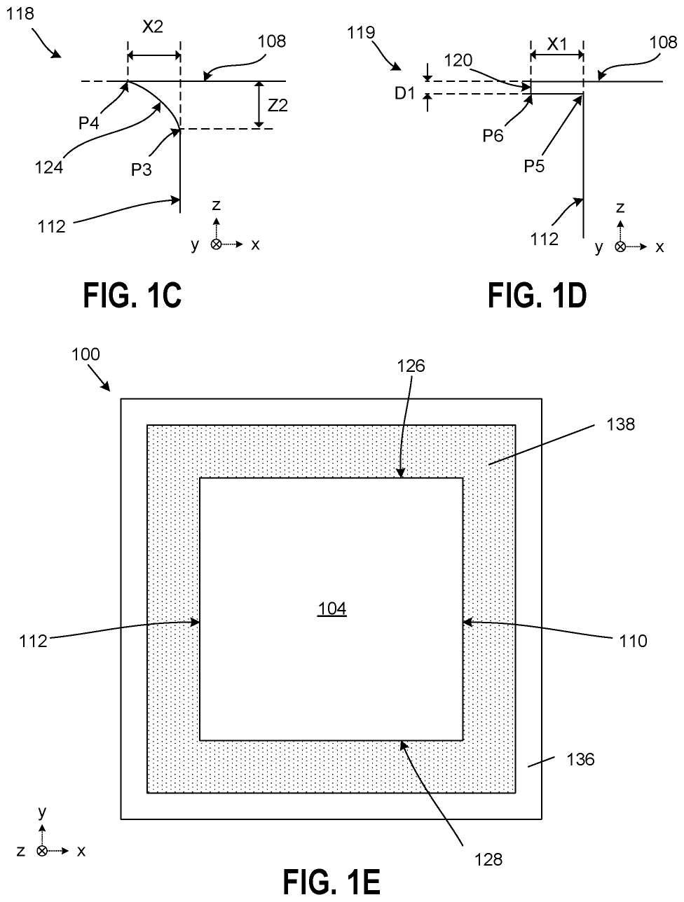

FIG. 1A is a cross-sectional side view of a device 100 comprising a main body structure having an overhang portion according to some embodiments. FIGS. 1B-D are cross-sectional side views of the overhang portion of FIG. 1A according to some embodiments. FIG. 1E is a cross-sectional plan view of device 100 along line A-A′ of FIG. 1A. The elements of FIGS. 1A-E and the following figures are presented for illustration, and are not drawn to scale.

As shown in FIG. 1A, device 100 comprises a main body structure 104 comprising an IC die. The IC die comprises one or more device layers and one or more metallization layers that are not shown in FIG. 1A so as to not to obscure novel aspects of the device 100. A film 114 contacts a backside 108 of the IC die. In some embodiments, the main body structure 104 of device 100 comprises a front side 106 and a backside 108 of the IC die. Backside 108 is at the interface of the IC die and film 114, or at the interface of the IC die and one or more optional thin layers between the IC die and film 114. Front side 106 and backside 108 are opposite one another. Main body structure 104 also comprises four sidewalls. (Because it is a cross-sectional view, only two sidewalls are shown in FIG. 1A.) In embodiments, sidewall 110 and 112 are sidewalls of the main body structure 104. In some embodiments, sidewall 110 and 112 are sidewalls of the IC die. Sidewalls 110 and 112 are opposite one another. In addition, each of sidewalls 110 and 112 are substantially perpendicular to backside 108 and front side 106.

In embodiments, device 100 comprises a film 114 on main body structure 104. In embodiments, film 114 is on backside 108 of the IC die. In embodiments, the film 114 is a DBF and comprises a thermal dissipation material. In various embodiments, film 114 has a thickness of 50 to 200 μm. In various embodiments, film 114 may be a material such as Cu, Al, Ag, Au, diamond, or SiC. In some embodiments, film 114 may be comprised of two or more of Cu, Al, Ag, Au, diamond, or SiC. In some embodiments, film 114 may be comprised of Cu and diamond, or Cu and a ceramic material. In some embodiments, as illustrated elsewhere herein, device 100 optionally comprises one or more layers between backside 108 and film 114. For example, device 100 may include a diffusion barrier or a buffer layer (to protect the IC die during deposition of the DBF) between backside 108 and film 114. The one or more layers between backside 108 and film 114 may comprise Ti, Ni, V, Au, N, or combinations of these or other materials, and have a thickness in the range of 10-500 nm.

In embodiments, main body structure 104 comprises an overhang portion 116. In some embodiments, the IC die comprises overhang portion 116. In embodiments, film 114 extends along the overhang portion 116. Overhang portion 116 extends away from sidewall 112 to a point outside a footprint of the IC die, as further described with reference to FIG. 1E.

As shown in FIG. 1B, overhang portion 116 of main body structure 104 adjoins sidewall structure 112. In some embodiments, overhang portion 116 comprises a second sidewall structure 120, which is substantially perpendicular to the backside 108 of the IC die. Second sidewall structure 120 has a height of D1, which may be 1 to 3 μm in various embodiments. Sidewall structure 112 lies in a z-y plane (not shown), and, in some embodiments, second sidewall structure 120 may be spaced away from the plane in which sidewall structure 112 lies by a distance X1 of 5 to 200 μm. In some embodiments, overhang portion 116 extends laterally away from sidewall structure 112 a distance X1 of 5 to 200 μm. In embodiments, overhang portion 116 comprises a transitional surface 122, which extends from point P1 of sidewall structure 112 to point P2 of second sidewall structure 120. In some embodiments, point P1 of sidewall structure 112 is spaced away from backside 108 by a distance Z1 of 5 to 12 μm. In some embodiments, the point P2 of second sidewall structure 120 is outside of a footprint of the IC die. In some embodiments, transitional surface 122 may be, in cross section, an inward curving or concave surface having a radius of curvature of about 5 to 15 μm. In some embodiments, transitional surface 122 may be a fillet. In some embodiments, transitional surface 122 may be, in cross section, an irregular surface or a substantially linear surface, such as a bevel or chamfer. It will be appreciated that the geometry of transitional surface 122 may vary with variations of a manufacturing process.

FIG. 1C shows an alternate overhang portion 118 according to some embodiments. Overhang portion 118 of main body structure 104 adjoins sidewall structure 112. Unlike overhang portion 116, overhang portion 118 may not have second sidewall structure 120. Instead, overhang portion 118 comprises a transitional surface 124, which extends from point P3 of sidewall structure 112 to point P4 of film 114. In embodiments, the z-axis thickness of overhang portion 118 is progressively reduced from a thickness of Z2 at point P3 until surface 124 reaches a thin featheredge at point P4 at backside 108. In some embodiments, point P3 is spaced away from backside 108 by a distance Z2 of 5 to 12 μm. In some embodiments, point P4 is spaced away from side wall 112 by a distance X2 of 5 to 200 μm. In some embodiments, transitional surface 124 may be, in cross section, an inward curving or concave surface having a radius of curvature of about 5 to 15 μm. In some embodiments, transitional surface 122 may be a fillet. In some embodiments, transitional surface 124 may be, in cross section, an irregular surface or a substantially linear surface, such as a bevel. It will be appreciated that the geometry of transitional surface 124 may vary with variations of a manufacturing process.

FIG. 1D shows an alternate overhang portion 119 according to some embodiments. Like overhang portion 116, overhang portion 119 includes second sidewall structure 120. Unlike overhang portions 116, 118, overhang portion 119 may not have transitional surface 122 or 124. As shown in FIG. 1D, overhang portion 116 of main body structure 104 adjoins sidewall structure 112. In an embodiment, overhang portion 116 comprises a second sidewall structure 120, which is substantially perpendicular to the backside 108 of the IC die. Second sidewall structure 120 has a height of D1, which may be 1 to 3 μm in various embodiments. Sidewall structure 112 lies in a z-y plane (not shown), and, in some embodiments, second sidewall structure 120 may be spaced away from the plane in which sidewall structure 112 lies by a distance X1 of 5 to 200 μm. In some embodiments, overhang portion 119 extends laterally away from sidewall structure 112 a distance X1 of 5 to 200 μm. In embodiments, overhang portion 119 extends from point P5 of sidewall structure 112 to point P6 of second sidewall structure 120. In some embodiments, the point P5 of sidewall structure 112 is spaced away from backside 108 by a distance of D1, which may be 1 to 3 μm in various embodiments. In some embodiments, the point P6 of second sidewall structure 120 is outside of a footprint of the IC die. It will be appreciated that the geometry of second sidewall structure 120 may vary with variations of a manufacturing process.

As shown in FIG. 1E, the IC die comprises four sidewalls 110, 112, 126, and 128, These four sidewalls, at line A-A′ of FIG. 1A (and below), define a footprint of the IC die. In an embodiment, sidewalls 110, 112, 126, and 128 define a footprint of the IC die on substrate 136, and overhang portions 116, 118 and 119 each extend outside horizontally past the footprint of the IC die on substrate 136. Referring again to FIGS. 1A-1D, it can be seen that overhang portions, e.g., overhang portions 116, 118 and 119, extend outside of the footprint of the IC die and laterally away from sidewalls 110, 112, 126, and 128 to points outside the footprint of the IC die. In embodiments, points P2, P4, and P6 are outside the footprint of the IC die while points P1, P3, and P5 are on or close to the perimeter of the footprint of the IC die.

Referring again to FIG. 1A, in some embodiments, device 100 includes a hardware interface 130 comprising bond pads, metal pins, pads, microbumps, balls and/or other conductive contacts 132 on the IC die, each of which are for coupling with a bond pad, metal pin, pad, microbump, ball and/or other conductive contact 134 of another structure. In the shown example, device 100 comprises a substrate 136 (e.g., an interposer, a package substrate, a circuit board, another IC die, or the like) comprising conductive contacts 134. In various embodiments, device 100 comprises underfill material 138 disposed on a top surface 140 of substrate 136, as well as around and on conductive contacts 132. Underfill material 138 is also disposed along and in contact with sidewalls 112, 110. Underfill material 138 may comprise organic polymers and inorganic fillers. Underfill 138 may be any of the materials described in operation 210 of method 200 below or may be other materials. Underfill 138 material may be applied using any of the techniques described in operation 210 of method 200 or may be applied using other means.

In some embodiments, main body structure comprises an exterior surface which comprises: front side 106, backside 108, sidewall structures 110, 112, 126, and 128, and overhang portion 116, 118 of the IC die.

Device 100 has been described with respect to the IC die, hardware interface 130, and substrate 136. It should be understood that device 100 is a simple example that omits various features of device 100 and is used in the description so as to not to obscure novel aspects of the device. It should be appreciated that device 100 is not limited to a single IC die. In various embodiments, device 100 may include multiple IC die in either side-by-side or stacked arrangements. In various embodiments, device 100 may include multiple IC die interconnected in any of variety or ways, e.g., via as hybrid bonding, an interposer, or solder bonding.

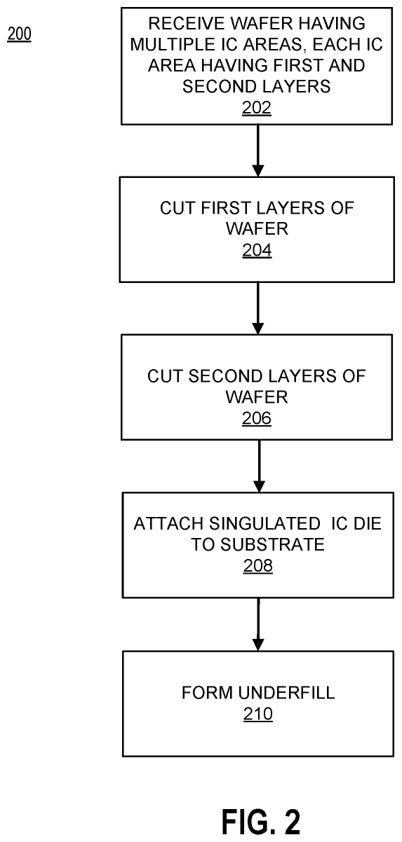

FIG. 2 illustrates a flow diagram of a method 200 for fabricating an IC package having an overhang portion according to some embodiments. Method 200 may include a plurality of operations, for example, operation 202 comprises receiving a microelectronic device wafer having multiple IC areas. In embodiments, the microelectronic device wafer may be wafer 600 described below. In embodiments, the microelectronic device wafer comprises first layers and second layers. First layers comprise one or more device layers and one or more metallization layers. First layers may be comprised of materials such as silicon. Second layers comprise one or more DBF layers comprised of materials, such as Cu, Al, Ag, Au, diamond, SiC, or Cu and a ceramic material. First layers may be contiguous and have a first thickness. Second layers may be contiguous and have a second thickness.

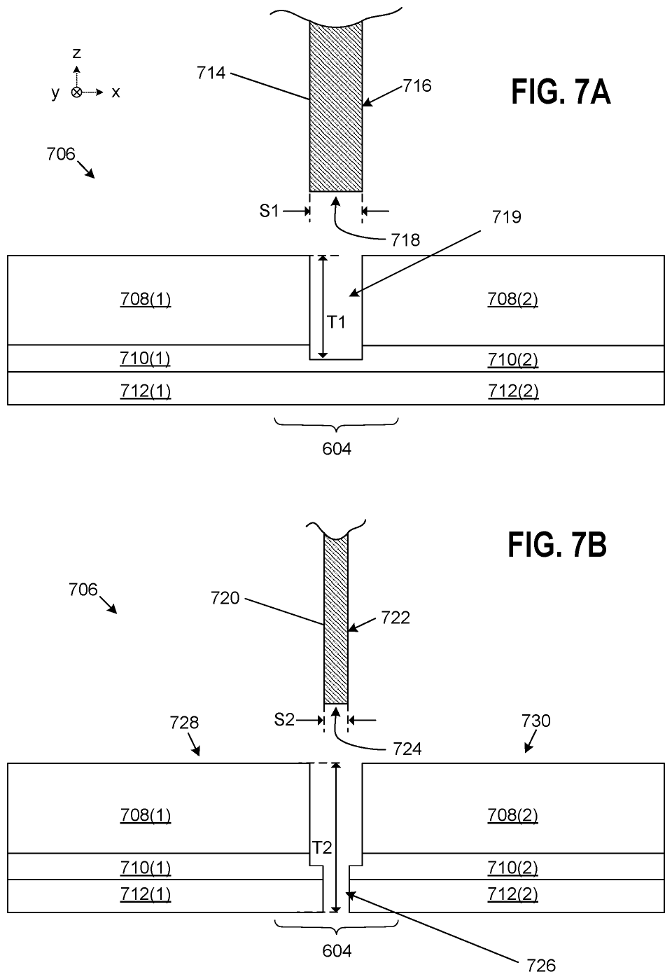

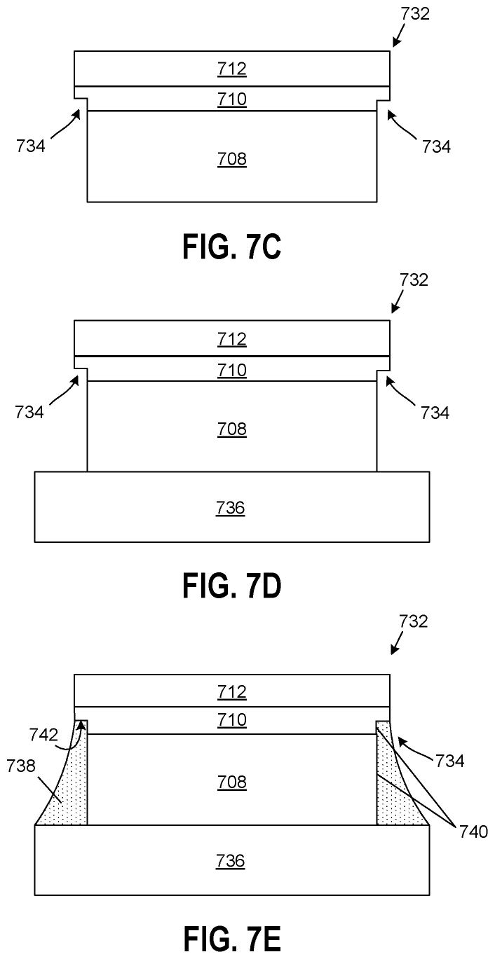

Operation 204 comprises cutting the microelectronic device wafer to a first depth along scribe streets separating the integrated circuit areas. In embodiments, the cutting operations are on a front side of the wafer where the first layers are disposed. For example, the wafer may be cut to a first depth corresponding with the thickness of the first layers of the wafer. The cutting operations in operation 204 may be performed using any suitable method. For example, cutting operations may be performed with a circular diamond-impregnated dicing saw. In some embodiments, mechanical dicing, laser ablation, laser milling, laser chemical etching, wet and dry etching, or reactive ion etching may be used to cut first layers in operation 204. In some embodiments, material may be removed to the predetermined depth using a plasma process. In various embodiments, the cutting operation results in a kerf or trench-shaped area referred to herein as a “kerf.” As shown in FIGS. 7A-B and 8A-B, cutting operation 204 result in a kerf or trench having the first depth, a first width, and a leading edge or kerf profile that may be substantially linear, substantially curved, or otherwise non-linearly shaped.

Operation 206 comprises cutting the microelectronic device wafer to a second depth sufficient to complete the singulation process. In operation 206, cuts are made along the centers of scribe streets separating the integrated circuit areas. The cutting operations in operation 206 may be performed using any suitable method. For example, cutting operations may be performed with a circular diamond-impregnated dicing saw, or via mechanical dicing, laser ablation, laser milling, laser chemical etching, wet and dry etching, or reactive ion etching. In some embodiments, a plasma process may be used to cut first layers in operation 206. As shown in FIGS. 7A-B and 8A-B, cutting operation 206 results in a kerf or trench having the second depth and a second width, wherein the second width is narrower than the first width of the kerf created in operation 204. In various embodiments, operation 206 results in the multiple integrated circuit areas of microelectronic device wafer being singulated into a corresponding number of IC dies.

In operation 208, a singulated IC die is attached to a substrate. Operation 208 generally comprises mechanically attaching and electrically coupling an IC die to the substrate. The IC die and the substrate may each have bond pads. In some embodiments, the IC die and the substrate are soldered together at the bond pads. In some embodiments, the IC die is directly bonded to the substrate, i.e., bonds are formed between both metallization features of the IC die and the substrate, and between dielectric materials of the IC die and the substrate.

At 210, an underfill is formed on the substrate in spaces under the IC die, such as between bond pads of IC die, and in areas adjacent to the IC die. For example, underfill may be formed along and adjoin sidewalls of the IC die. In various embodiments, underfill material comprises any of various organic compounds which (for example) are adapted from any of various materials used as an underfill in some existing packaging techniques. In some embodiments, the underfill material comprises an organic polymer including, but are not limited, any of various epoxy resins—e.g., bisphenol A resins, bisphenol F resins, cycloaliphatic epoxy resins, and mixtures thereof—cyanate esters, siloxiranes, maleimides, polybenzoxazines, polyimides, silicones, epoxy-acrylates, liquid crystal polymers, or the like (including any of various combinations and/or derivatives thereof). In an embodiment, the underfill material further comprises fillers—such as particulates or fibers of silica and/or any of various other suitable materials. Underfill material may be applied by a variety of methods, including, but not limited to, printing, spin coating, or vacuum dispensing. In some embodiments, operation 210 comprises curing the underfill material, for example, by heat, ultra-violet (UV) light, and/or the like. In some embodiments, underfill is formed using transfer and compression molding processes.

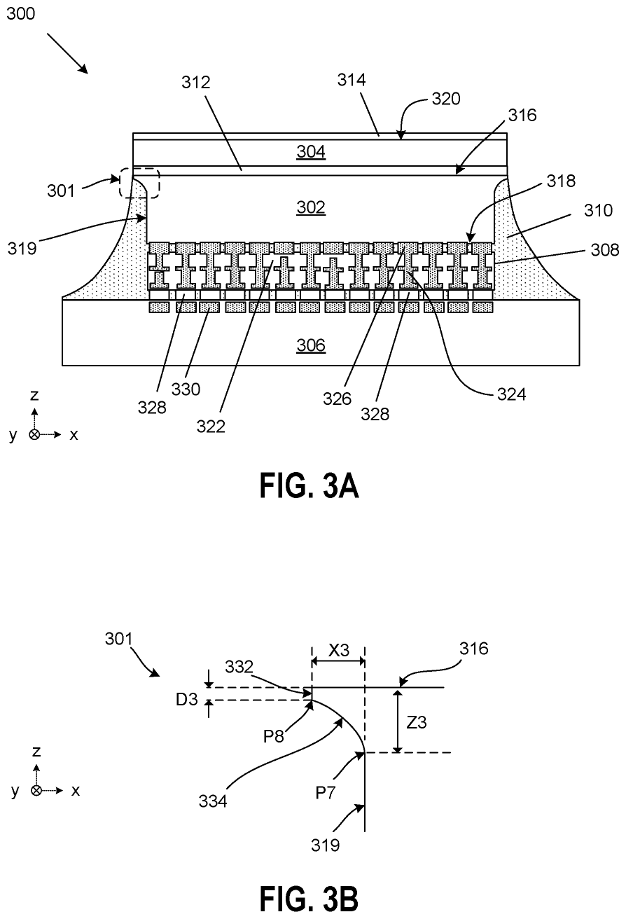

FIG. 3A is a simplified cross-sectional side view of a device 300 comprising a monolithic die that includes an overhang portion 301 according to various embodiments. In embodiments, device 300 comprises an IC die 302, a DBF 304, a package substrate 306, an interposer 308, and underfill material 310. Device 300 optionally may include an adhesion layer 312, a backside metal (BSM) layer 314, or both layers 312 and 314.

In embodiments, IC die 302 comprises a backside 316, which is opposite a front side 318. While IC die 302 comprises one or more device layers and one or more metallization layers, these layers are not shown in order to not obscure features pertinent to this disclosure. In embodiments, IC die 302 comprises a sidewall 319, which is substantially perpendicular to backside 316 and extends from front side 318 to backside 316.

In various embodiments, DBF 304 comprises a thermal dissipation material. In embodiments, DBF 304 can comprise any of the materials of which film 114 is comprised. In some embodiments, DBF 304 may be Cu, a composition of Cu and a ceramic, or a composition of Cu and diamond. In various embodiments, DBF 304 has a thickness of 50 to 200 μm. Adhesion layer 312 may optionally be disposed between DBF 304 and backside 316 of IC die 302. Adhesion layer 312 can comprise Ti, Ni, V, Au, SiN, or combinations thereof. BSM layer 314 may optionally be disposed on a top side 320 of DBF 304. BSM layer 314 can comprise Ti, Ni, V, Au, SiN, or combinations thereof.

IC die 302 communicates with package substrate 306 using interposer 308. In various embodiments, interposer 308 comprises mold material structure 322 and a plurality of through-mold vias (TMVs) 324. Interposer 308 comprises one or more conductive contacts 326 at a side of interposer 308 that faces front side 318 of the IC die 302. In addition, interposer 308 comprises one or more conductive contacts 328 at a side of the interposer 308 that faces substrate 306. As shown in FIG. 3A, conductive contacts 326 and 328 may be coupled with one or more of TMVs 324. In embodiments, conductive contacts 326 and 328 may be bond pads or other metal interconnect features. IC die 302 comprises interconnect features (not shown) and conductive contacts 326 contact the interconnect features of IC die 308, thereby coupling IC die 302 to interposer 308. Package substrate 306 comprises interconnect features 330 and conductive contacts 328 contact the interconnect features 330 of substrate 306, thereby coupling substrate 306 to interposer 308. In embodiments, interconnect features of IC die 302 and interconnect features 330 may be bond pads or other metal interconnect features.

FIG. 3B is a cross-sectional side view of the overhang portion 301 of FIG. 3A according to some embodiments.

As shown in FIG. 3B, overhang portion 301 of main body structure adjoins sidewall structure 319. In some embodiments, overhang portion 301 comprises a second sidewall structure 332, which is substantially perpendicular to the backside 316 of IC die 302. Second sidewall structure 332 has a height of D3, which may be 1 to 3 μm in various embodiments. Sidewall structure 319 lies in a z-y plane (not shown), and, in some embodiments, second sidewall structure 332 may be spaced away from the plane in which sidewall structure 319 lies by a distance X3 of 5 to 200 μm. In some embodiments, overhang portion 301 extends laterally away from sidewall structure 319 a distance X3 of 5 to 200 μm. In embodiments, overhang portion 301 comprises a transitional surface 334, which extends from point P7 of sidewall structure 319 to point P8 of second sidewall structure 332. In some embodiments, point P7 of sidewall structure 319 is spaced away from backside 316 by a distance Z3 of 5 to 12 μm. In some embodiments, the point P8 of second sidewall structure 332 is outside of a footprint of IC die 302. In some embodiments, transitional surface 334 may be, in cross section, an inward curving or concave surface having a radius of curvature of about 5 to 15 μm. In some embodiments, transitional surface 334 may be a fillet. In some embodiments, transitional surface 334 may be, in cross section, an irregular surface or a substantially linear surface, such as a bevel or chamfer. It will be appreciated that the geometry of transitional surface 334 may vary with variations of a manufacturing process.

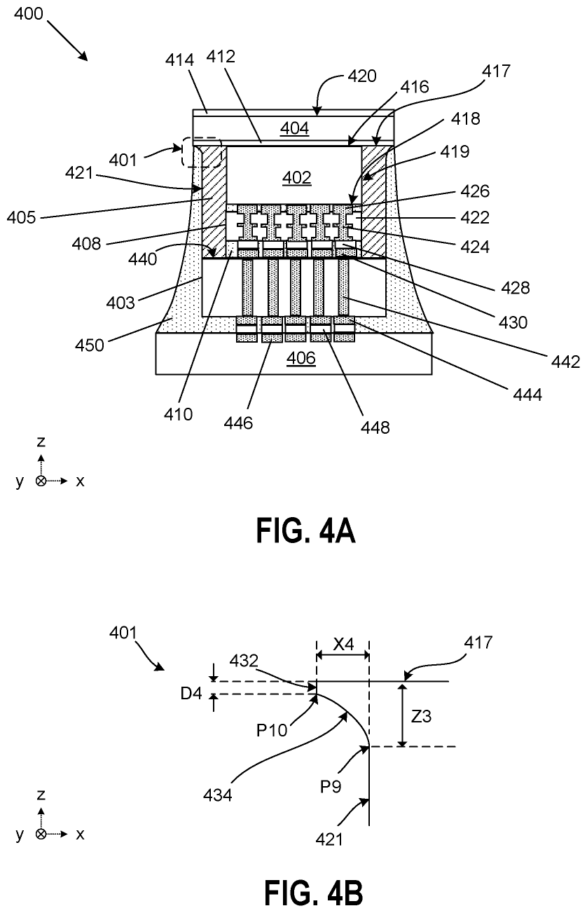

FIG. 4A is a simplified cross-sectional side view of a device 400 comprising a top IC die 402, a bottom IC die 403, and a mold structure 405 around the top IC die 402, wherein the mold structure 405 comprises an overhang portion 401, according to various embodiments. In embodiments, top IC die 402 is stacked on an interposer 408, which is stacked on bottom IC die 403. The bottom IC die 403 has a larger area or footprint than the top IC die 402, which provides a surface on which to form mold structure 405. In embodiments, mold structure 405 is formed on front side surface 440 of bottom IC die 403 and along sidewalls 419 of the top IC die 402. IC die 403 is disposed on a package substrate 406. A DBF 404 is disposed on top IC die 402 and mold structure 405.

In embodiments, top IC die 402 comprises a backside 416, which is opposite a front side 418. While top IC die 402 can comprise one or more device layers and one or more metallization layers, these layers are not shown in order to not obscure features pertinent to this disclosure.

Top IC die 402 communicates with bottom IC die 403 using interposer 408. In various embodiments, interposer 408 comprises inner mold material structure 422 and a plurality of through-mold vias (TMVs) 424. Interposer 408 comprises one or more conductive contacts 426 at a side of interposer 408 that faces front side 418 of top IC die 402. Top IC die 402 comprises interconnect features (not shown) and conductive contacts 426 contact the interconnect features of interposer 408, thereby coupling top IC die 402 to interposer 408. In embodiments, conductive contacts 426 may be bond pads or other metal interconnect features.

In embodiments, bottom IC die 403 comprises conductive contacts 430 on front surface 440 of bottom IC die 403. Respective ones of conductive contacts 430 of bottom IC die 403 are coupled with TMVs 424 of interposer 408 via solder bonds 428. In embodiments, conductive contacts 430 may be bond pads or other metal interconnect features. In some embodiments, interposer 408 comprises first underfill material 410, which may be disposed around conductive contacts 426 and 430. Underfill 410 may be any of the materials described in operation 210 of method 200 or may be other materials. Underfill 410 material may be applied using any of the techniques described in operation 210 of method 200 or may be applied using other means.

Bottom IC die 403 comprises a plurality of through-silicon vias (TSVs) 442 and conductive contacts 444 at a side of bottom IC die 403 opposite front side surface 440. One or more of TSVs 442 may be coupled with one of conductive contacts 444, or one or more of conductive contacts 430, or with both contacts 444, 430. In embodiments, bottom IC die 403 comprises one or more device layers and one or more metallization layers; however, these layers are not shown in order to not obscure features pertinent to this disclosure.

Package substrate 406 comprises conductive contacts 446. In embodiments, IC die 403 is mechanically attached and electrically coupled to package substrate 406. In embodiments, IC die 403 is attached and coupled to substrate 406 via solder bonds 448 between conductive contacts 444 of bottom IC die 403 and conductive contacts 446 of package substrate 406. In embodiments, conductive contacts 444 and 446 may be bond pads or other metal interconnect features.

As mentioned, mold structure 405 is formed on front side surface 440 of bottom IC die 403 and along sidewalls 419 of the top IC die 402. Mold structure 405 comprises a top surface 417, which is opposite a surface of mold structure 405 that contacts front side surface 440 of bottom IC die 403. In embodiments, mold structure 405 comprises a sidewall 421 which is substantially perpendicular to backside 416 of top IC die 402. In addition, in embodiments, sidewall 421 substantially perpendicular to top surface 417 of mold structure 405. In various embodiments, DBF 404 is formed on top surface 417 of mold structure 405 and on backside 416 of top IC die 402.

In various embodiments, DBF 404 comprises a thermal dissipation material. In embodiments, DBF 404 can comprise any of the materials of which film 114 is comprised. In some embodiments, DBF 404 may be Cu, a composition of Cu and a ceramic, or a composition of Cu and diamond. In various embodiments, DBF 404 has a thickness of 50 to 200 μm. In some embodiments, device 400 optionally may include an adhesion layer 412, a backside metal (BSM) layer 414, or both layers 412 and 414. Where adhesion layer 412 is employed, it is disposed between DBF 404 on one side, and backside 416 and surface 417 on an opposite side. BSM layer 414 may be disposed on a top side 420 of DBF 404. Adhesion layer 412 can comprise Ti, Ni, V, Au, SiN, or combinations thereof. BSM layer 414 can comprise Ti, Ni, V, Au, SiN, or combinations thereof.

In various embodiments, second underfill material 450 may disposed on package substrate 406. Second underfill material 450 may be disposed around conductive contacts 444 of bottom IC die 403. Second underfill material 450 may contact and extend along sidewalls of bottom IC die 403. In addition, second underfill material 450 can contact and extend along sidewalls 419 of sidewall 421 of mold structure 405. Second underfill material 450 may be any of the materials described in operation 210 of method 200 or may be other materials. Second underfill material 450 may be applied using any of the techniques described in operation 210 of method 200 or may be applied using other means.

FIG. 4B is a cross-sectional side views of the overhang portion 401 of FIG. 4A according to some embodiments. As shown in FIG. 4B, overhang portion 401 adjoins sidewall structure 421 of mold structure 405. In some embodiments, overhang portion 401 comprises a second sidewall structure 432, which is substantially perpendicular to the backside 416 of IC die 402 and top surface 417 of mold structure 405. Second sidewall structure 432 has a height of D4, which may be 1 to 3 μm in various embodiments. Sidewall structure 421 lies in a z-y plane (not shown), and, in some embodiments, second sidewall structure 432 may be spaced away from the plane in which sidewall structure 421 lies by a distance X4 of 5 to 200 μm. In some embodiments, overhang portion 401 extends laterally away from sidewall structure 421 a distance X4 of 5 to 200 μm. In embodiments, overhang portion 401 comprises a transitional surface 434, which extends from point P9 of sidewall structure 421 to point P10 of second sidewall structure 432. In some embodiments, point P9 of sidewall structure 421 is spaced away from top surface 417 by a distance Z3 of 5 to 12 μm. In some embodiments, the point P10 of second sidewall structure 432 is outside of a footprint of mold structure 405. In some embodiments, transitional surface 434 may be, in cross section, an inward curving or concave surface having a radius of curvature of about 5 to 15 μm. In some embodiments, transitional surface 434 may be a fillet. In some embodiments, transitional surface 434 may be, in cross section, an irregular surface or a substantially linear surface, such as a bevel or chamfer. It will be appreciated that the geometry of transitional surface 434 may vary with variations of a manufacturing process.

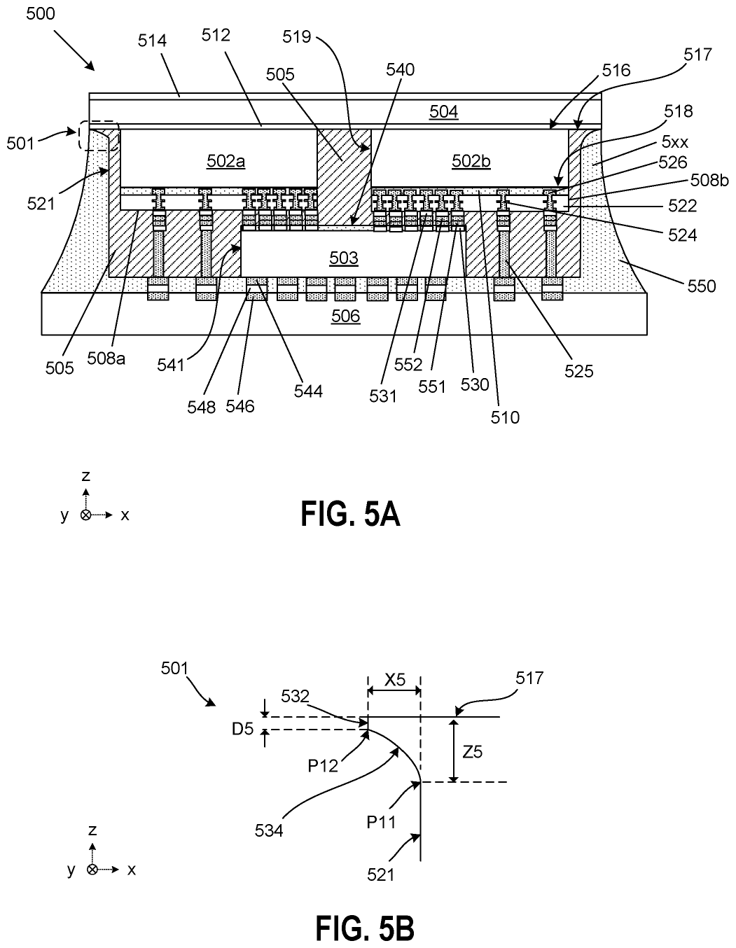

FIG. 5A is a simplified cross-sectional side view of a device 500 comprising two or more top IC dies 502, a bottom IC die 503, and a mold structure 505 around the top IC dies 502 and bottom IC die 503, wherein the mold structure 505 comprises an overhang portion 501, according to various embodiments. In embodiments, device 500 comprises top IC dies 502a and 502b (collectively “top IC dies 502) and interposers 508a and 508b (collectively “interposers 508”). In embodiments, each of top dies 502 is stacked on of respective one of interposers 508, and interposers 508 are stacked on bottom IC die 503. In various embodiments, bottom IC die 503 is disposed on a package substrate 506. In embodiments, a DBF 504 is disposed on top IC dies 502 and mold structure 505.

Top IC dies 502 may be substantially the same. In addition, interposers 508 may be substantially the same. For this reason, features of top IC die 502 and interposer 508 are described with respect to a single instance of each, i.e., top IC die 502b and interposer 508b. It should be understood that this description applies equally to both top IC dies 502 and both interposers 508. In embodiments, top IC die 502b comprises a backside 516, which is opposite a front side 518. While top IC dies 502 can comprise one or more device layers and one or more metallization layers, these layers are not shown in order to not obscure features pertinent to this disclosure.

Top IC die 502b is communicates with bottom IC die 503 using interposer 508b. In various embodiments, interposer 508b comprises inner mold material structure 522 and a plurality of through-mold vias (TMVs) 524. Interposer 508 comprises one or more conductive contacts 526 at a side of interposer 508 that faces front side 518 of top IC die 502b. Top IC die 502b comprises interconnect features (not shown) and conductive contacts 526 contact the interconnect features of interposer 508b, thereby coupling top IC die 502b to interposer 508b. In embodiments, conductive contacts 526 may be bond pads or other metal interconnect features.

In embodiments, bottom IC die 503b comprises conductive contacts 530 on front surface 540 of bottom IC die 503b. Respective ones of conductive contacts 530 of bottom IC die 503b are coupled with conductive contacts 531 of TMVs 524 of interposer 508b via solder bonds 551, 552. In embodiments, conductive contacts 530 and 531 may be bond pads or other metal interconnect features. In some embodiments, interposer 508b comprises first underfill material 510, which may be disposed around conductive contacts 530 and 531. Underfill material 510 may be any of the materials described in operation 210 of method 200 or may be other materials. Underfill material 510 material may be applied using any of the techniques described in operation 210 of method 200 or may be applied using other means.

In addition to conductive contacts 530 at front side surface 540, bottom IC die 503 comprises a plurality of conductive contacts 544 at a side of bottom IC die 503 opposite front side surface 540. In embodiments, bottom IC die 503 comprises one or more device layers and one or more metallization layers; however, these layers are not shown in order to not obscure features pertinent to this disclosure.

Package substrate 506 comprises conductive contacts 546. In embodiments, bottom IC die 503 is mechanically attached and electrically coupled to package substrate 506. In embodiments, bottom IC die 503 is attached and coupled to substrate 506 via solder bonds 548 between conductive contacts 544 of bottom IC die 503 and conductive contacts 546 of package substrate 506. In embodiments, conductive contacts 544 and 546 may be bond pads or other metal interconnect features.

As mentioned, device 500 comprises mold structure 505, which is formed around the top IC dies 502 and bottom IC die 503. In embodiments, top surface 517 of mold structure 505 is formed on DBF 504, or as shown in FIG. 5A, on optional adhesion layer 512. In addition, in embodiments, mold structure 505 contacts bottom IC die 503 at front side surface 540 and sidewalls 541. In embodiments, mold structure 505 also contacts and extends along sidewalls 519 of the top IC dies 502a, 502b. Mold structure 505 comprises a top surface 517, which is opposite a surface of mold structure 505 that contacts front side surface 540 of bottom IC die 503. In embodiments, mold structure 505 comprises a sidewall 521 which is substantially perpendicular to backside 516 of top IC die 502. In addition, in embodiments, sidewall 521 substantially perpendicular to top surface 517 of mold structure 505. In embodiments, device 500 comprises a plurality of second TMVs 525 that extend through mold structure 505, coupling interposers 508a, 508b with package substrate 506. As mentioned, in various embodiments, DBF 504 is formed on top surface 517 of mold structure 505 and on backside 516 of top IC dies 502a, 502b.

In various embodiments, DBF 504 comprises a thermal dissipation material. In embodiments, DBF 504 can comprise any of the materials of which film 114 is comprised. In some embodiments, DBF 504 may be Cu, a composition of Cu and a ceramic, or a composition of Cu and diamond. In various embodiments, DBF 504 has a thickness of 50 to 200 μm. In some embodiments, device 500 optionally may include an adhesion layer 512, a backside metal (BSM) layer 514, or both layers 512 and 514. Where adhesion layer 512 is employed, it is disposed between DBF 504 on one side, and backside 516 and surface 517 on an opposite side. BSM layer 514 may be disposed on a top side 520 of DBF 504. Adhesion layer 512 can comprise Ti, Ni, V, Au, SiN, or combinations thereof. BSM layer 514 may optionally be disposed on a top side 320 of DBF 304. BSM layer 314 can comprise Ti, Ni, V, Au, SiN, or combinations thereof.

In various embodiments, second underfill material 550 may disposed on package substrate 506. Second underfill material 550 may be disposed around conductive contacts 544 of bottom IC die 503. Second underfill material 550 may contact and extend along sidewalls 521 of bottom IC die 503 of mold structure 505. Second underfill material 550 may be any of the materials described in operation 210 of method 200 or may be other materials. Second underfill material 550 material may be applied using any of the techniques described in operation 210 of method 200 or may be applied using other means.

FIG. 5B is a cross-sectional side views of the overhang portion 501 of FIG. 5A according to some embodiments. As shown in FIG. 5B, overhang portion 501 adjoins sidewall structure 521 of mold structure 505. In some embodiments, overhang portion 501 comprises a second sidewall structure 532, which is substantially perpendicular to the backsides 516 of IC dies 502a, 502b and top surface 517 of mold structure 505. Second sidewall structure 532 has a height of D5, which may be 1 to 3 μm in various embodiments. Sidewall structure 521 lies in a z-y plane (not shown), and, in some embodiments, second sidewall structure 532 may be spaced away from the plane in which sidewall structure 521 lies by a distance X5 of 5 to 200 μm. In some embodiments, overhang portion 501 extends laterally away from sidewall structure 521 a distance X5 of 5 to 200 μm. In embodiments, overhang portion 501 comprises a transitional surface 534, which extends from point P11 of sidewall structure 521 to point P12 of second sidewall structure 532. In some embodiments, point P11 of sidewall structure 521 is spaced away from top surface 517 by a distance Z5 of 5 to 12 μm. In some embodiments, the point P12 of second sidewall structure 532 is outside of a footprint of mold structure 505. In some embodiments, transitional surface 534 may be, in cross section, an inward curving or concave surface having a radius of curvature of about 5 to 15 μm. In some embodiments, transitional surface 534 may be a fillet. In some embodiments, transitional surface 534 may be, in cross section, an irregular surface or a substantially linear surface, such as a bevel or chamfer. It will be appreciated that the geometry of transitional surface 534 may vary with variations of a manufacturing process.

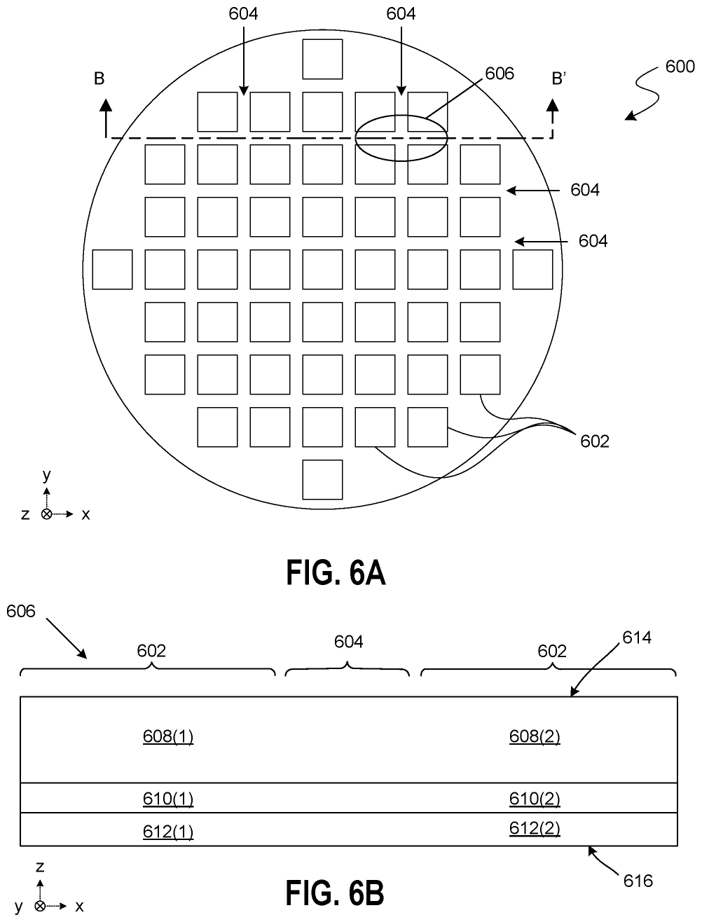

FIG. 6A is a top plan view of a microelectronic device wafer 600 to which embodiments of a two-step singulation process may be applied according to various embodiments. As shown in FIG. 6A, wafer 600 comprises a plurality of IC areas 602, which may be substantially rectangular and arranged in rows and columns Between IC areas 602 are two sets of mutually parallel sets of lines or “scribe streets” 604, which extend perpendicular to each other. The scribe streets 604 are sized to allow passage of a wafer saw blade or the performance of another singulation process between adjacent IC areas 602 without causing damage to circuitry within any of the IC areas 602.

In various embodiments, the internal structure of IC areas 602 may be substantially identical. In embodiments, each IC 602 area may include one or more device layers having active and/or passive devices fabricated during front-end-of-line (FEOL) processing. Each IC area 602 may include one or more back-end-of-line (BEOL) metallization layers fabricated over a device layer. The active and passive devices of a device layer are interconnected into circuitry with metal structures within one or more metallization layers. In various embodiments, each IC area 602 includes a DBF at a backside of the IC die. The DBF may be one or more layers of the wafer. The DBF may cover substantially all of the backside of the wafer.

FIG. 6B is a side cross-sectional view of portion 606 of microelectronic device wafer 600 along line B-B′ of FIG. 6A according to various embodiments. As shown in FIG. 6B, portion 606 of wafer 600 includes two IC areas 602, each comprising device layers 608a, 608b, metallization layers 610a, 610b, and DBF layers 612a, 612b. A scribe street 604 is disposed between the two IC areas 602. Device layers 608a, 608b are disposed at a front side 614 of the wafer. DBF layers 612a, 612b are disposed at a back side 616 of the wafer. Method 200 refers to “first layers” and “second layers.” In embodiments, device layers 608 and metallization layers 610 are first layers, and DBF layers 612 are second layers.

FIGS. 7A through 7E show cross-sectional side views diagrams, each illustrating respective stages of a process to form an IC package according to various embodiments.

FIG. 7A illustrates portion 706 of microelectronic device wafer 600 after the wafer has been cut to a first depth along scribe street 604 in a first step of a two-step singulation process. In embodiments, portion 706 may be the same as portion 606. In the example of FIG. 7A, wafer 600 has been cut to a first depth T1. In an embodiment, the first depth T1 may be equal to the depth of the device layers 708a, 708b plus all or a portion of the depth of metallization layers 710a, 710b. As shown in FIG. 7A, the first depth T1 may include a portion of the depth of metallization layers 710 that is less than the entire depth of metallization layers 710. In other embodiments, the first depth T1 may include the entire depth of metallization layers 710. In some embodiments, first depth T1 does not extend into DBF layers 712.

In the example shown in FIG. 7A, cutting operations in the first step are performed with a circular diamond-impregnated dicing saw that is substantially centered on scribe street 604. Reference number 714 identifies a cross-section of a dicing blade having a kerf width S1, sides 716, and a kerf profile 718. In embodiments, kerf profile 718 is straight or flat and perpendicular to sides 716. Due to kerf width S land kerf profile 718, use of dicing blade 714 results in a cut or trench 719 having a width of about S1, straight sidewalls, and a flat bottom.

FIG. 7B illustrates portion 706 of microelectronic device wafer 600 after wafer 600 has been cut to a second depth along scribe street 604 in a second step of a two-step singulation process. In the example of FIG. 7B, wafer 600 has been cut to a second depth T2. In an embodiment, the second depth T2 may be equal to the depth of wafer 600.

In the example shown in FIG. 7B, cutting operations in the second step are performed with a circular diamond-impregnated dicing saw that is substantially centered on scribe street 604. Reference number 720 identifies a cross-section of a dicing blade having a kerf width S2, sides 722, and a kerf profile 724. In embodiments, kerf profile 724 is straight and perpendicular to sides 722. In embodiments, kerf width S2 is narrower than kerf width S1. Due to a kerf width S2 and kerf profile 724, use of dicing blade 720 results in a cut or trench 726 having a width S2 and straight of flat sidewalls. As shown in FIG. 7B, cutting operations in the second step result in singulated IC dies 728, 730.

FIG. 7C illustrates an IC die singulated according to a two-step singulation process, such as the process depicted in FIGS. 7A-7B. As shown in FIG. 7C, IC die 732 is flipped from the orientation of IC dies 728, 730 shown in FIG. 7B. IC die 732 comprises device layer 708, metallization layer 710, DBF layer 712, and overhang portions 734. FIG. 7D shows IC die 732 after it has been attached to a substrate 736 according to various embodiments. FIG. 7E shows IC die 732 after underfill 738 has been formed on substrate 736. Underfill 738 may be formed in spaces under the IC die, such as between bond pads of IC die, in areas adjacent to sidewalls 740 of IC die 732, and in areas adjacent to overhang portions 734. Underfill 738 may contact or adjoin sidewalls 740 and overhang portions 734. Underfill 738 may be contained by overhang portion 734, which may improve its adhesion to the sidewall. Underfill 738 may be any of the materials described in operation 210 of method 200 or may be other materials. Underfill 738 material may be applied using any of the techniques described in operation 210 of method 200 or may be applied using other means.

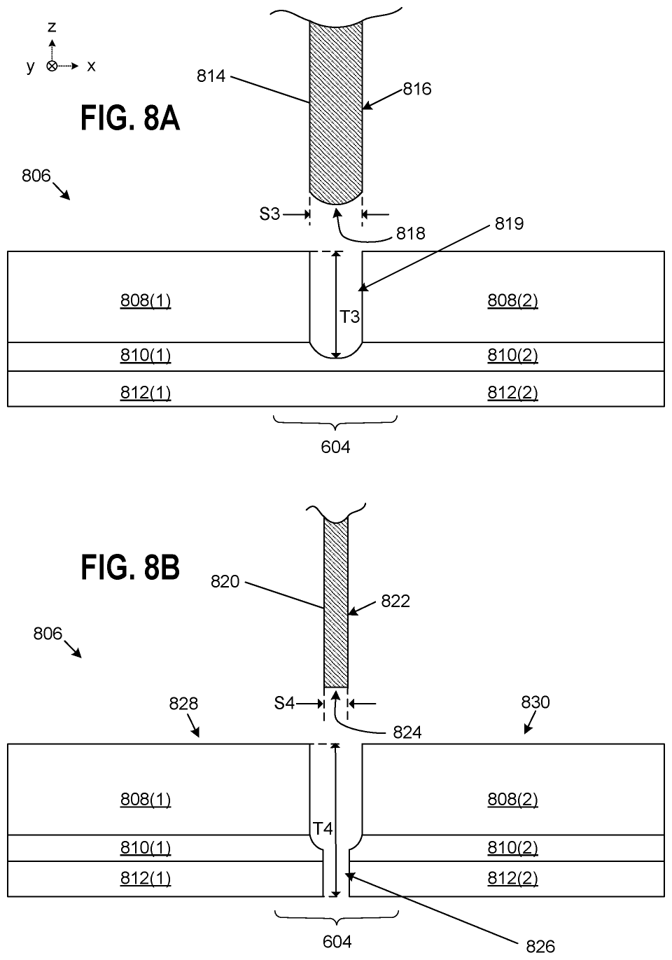

As illustrated and described in FIGS. 7A-7E, the cut or trench 719 is cut with a dicing blade 714 having a kerf profile 718 that is straight and perpendicular to sides 716. As a result, cut or trench 719 comprises a substantially straight or flat bottom portion that is perpendicular to sidewalls 740, and overhang portion 734 comprises a surface 742 that that is perpendicular to sidewalls 740. Embodiments are not limited to the cutting tools shown in FIGS. 7A-7B. Any of the cutting methods of operation 204 may be used in various embodiments. In addition, the cutting tools depicted in FIGS. 8A-8B may be used in some embodiments. Embodiments are not limited to the kerf profiles shown in FIGS. 7A-7B. Some embodiments may comprise the kerf profiles shown in FIGS. 8A-8B. Various embodiments may comprise kerf profile or trench bottom portion that has a curved, beveled, or other suitable shape.

FIG. 8A illustrates portion 806 of microelectronic device wafer 600 after the wafer has been cut to a first depth along scribe street 604 in a first step of a two-step singulation process. In embodiments, portion 806 may be the same as portion 606 shown in FIG. 6B. In the example of FIG. 8A, wafer 600 has been cut to a first depth T3. In an embodiment, the first depth T3 may be equal to the depth of the device layers 808(1), 808(2) plus all or a portion of the depth of metallization layers 810(1), 810(2). As shown in FIG. 8A, the first depth T1 may include a portion of the depth of metallization layers 810 that is less than the entire depth of metallization layers 810. In other embodiments, the first depth T1 may include the entire depth of metallization layers 810. In some embodiments, first depth T1 does not extend into DBF layers 812(1), 812(2).

In the example shown in FIG. 8A, cutting operations in the first step are performed with a circular diamond-impregnated dicing saw that is substantially centered on scribe street 604. Reference number 814 identifies a cross-section of a dicing blade having a kerf width S3, sides 816, and a kerf profile 818. In embodiments, kerf profile 818 is a curve shape. Due to kerf width S3 and kerf profile 818, use of dicing blade 814 results in a cut or trench 819 having a width of about S3, straight sidewalls, and a concave, curved bottom. Embodiments are not limited to the cutting tool shown in FIG. 8A. In various embodiments, any of the cutting methods of operation 204 may be used to create a trench having the profile shown in FIG. 8A.

FIG. 8B illustrates portion 806 of microelectronic device wafer 600 after wafer 600 has been cut to a second depth along scribe street 604 in a second step of a two-step singulation process, resulting in singulated IC die 828, 830. In the example of FIG. 8B, wafer 600 has been cut to a second depth T2. In an embodiment, the second depth T2 may be equal to the depth of wafer 600.

In the example shown in FIG. 8B, cutting operations in the second step are performed with a circular diamond-impregnated dicing saw that is substantially centered on scribe street 604. Reference number 820 identifies a cross-section of a dicing blade having a kerf width S2, sides 822, and a kerf profile 824. In embodiments, kerf profile 824 is straight and perpendicular to sides 822. In embodiments, kerf width S4 is narrower than kerf width S3. Due to a kerf width S4 and kerf profile 824, use of dicing blade 820 results in a cut or trench 826 having a width S2 and straight sidewalls.

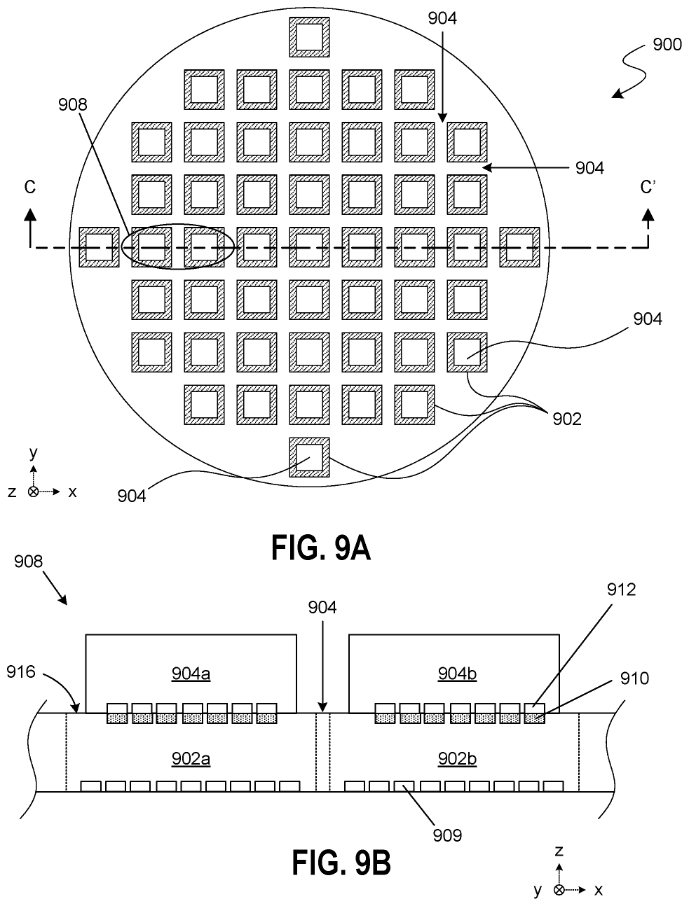

FIG. 9A is a top plan view of a microelectronic device wafer 900 to which embodiments of a two-step singulation process may be applied according to various embodiments. As shown in FIG. 9A, wafer 900 comprises a plurality of IC areas 902, which may be substantially rectangular and arranged in rows and columns Between IC areas 902 are two sets of mutually parallel sets of lines or “scribe streets” 904, which extend perpendicular to each other. The scribe streets 904 are sized to allow passage of a wafer saw blade or the performance of another singulation process between adjacent IC areas 902 without causing damage to circuitry within any of the IC areas 902.

A plurality of IC dies 904 are disposed on wafer 900 in locations corresponding with the IC areas 902. In an embodiment, an IC die 904 may be centered on an IC area 902. While the example of FIG. 9A shows a single IC die 904 per IC area 902, in other embodiments, two or more IC die 904 may be disposed on an IC area 902. IC dies 906 may be mechanically attached and electrically coupled with corresponding IC areas 902, such as via solder or direct bonding techniques.

In various embodiments, the internal structure of IC areas 902 may be substantially identical. In embodiments, each IC 902 area may include one or more device layers having active and/or passive devices fabricated during front-end-of-line (FEOL) processing. Each IC area 902 may include one or more back-end-of-line (BEOL) metallization layers fabricated over a device layer. The active and passive devices of a device layer are interconnected into circuitry with metal structures within one or more metallization layers.

In various embodiments, the internal structure of IC dies 904 may be substantially identical. In embodiments, each IC die 904 area may include one or more device layers having active and/or passive devices fabricated during front-end-of-line (FEOL) processing. Each IC die 904 may include one or more back-end-of-line (BEOL) metallization layers fabricated over a device layer. The active and passive devices of a device layer are interconnected into circuitry with metal structures within one or more metallization layers. In various embodiments, each IC die 904 includes a DBF at a backside of the IC die. The DBF may be one or more layers of the wafer. The DBF may cover substantially all of the backside of the die.

FIG. 9B is a side cross-sectional view of portion 908 of microelectronic device wafer 900 along line C-C′ of FIG. 9A according to various embodiments. As shown in FIG. 9B, portion 908 of wafer 900 includes two IC areas 902a, 902b, each comprising set of conductive contacts 909 and 910. A scribe street 904 is disposed between IC areas 902a, 902b. IC dies 904a, 904b are disposed on respective backside surfaces 916 of IC areas 902a, 902b. IC dies 904a, 904b comprise conductive contacts 912, which are in contact with conductive contacts 910.

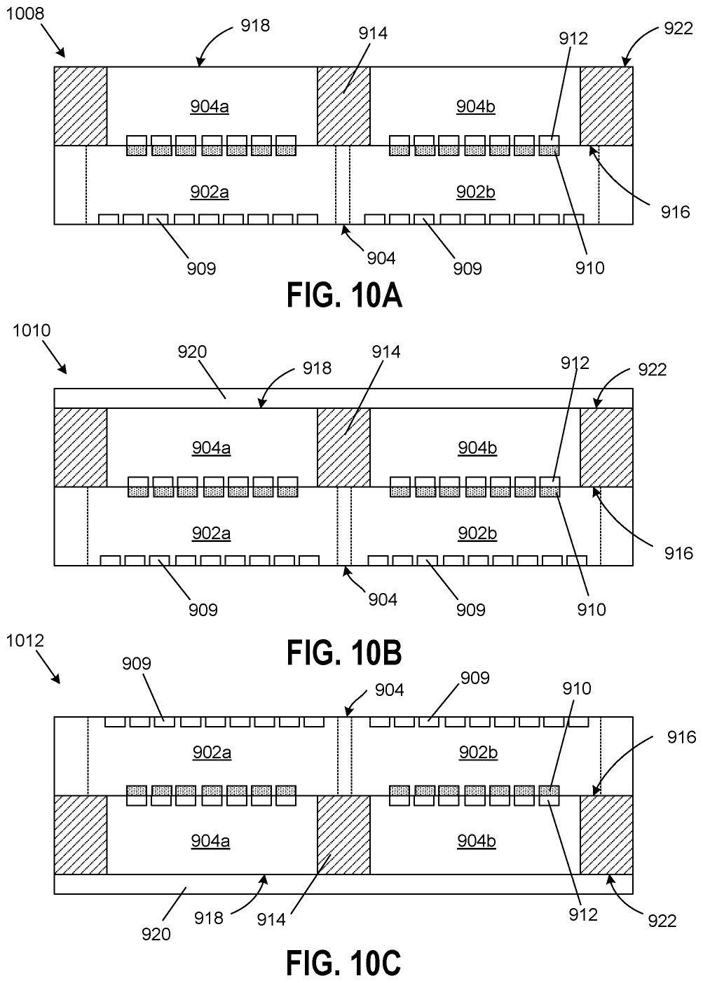

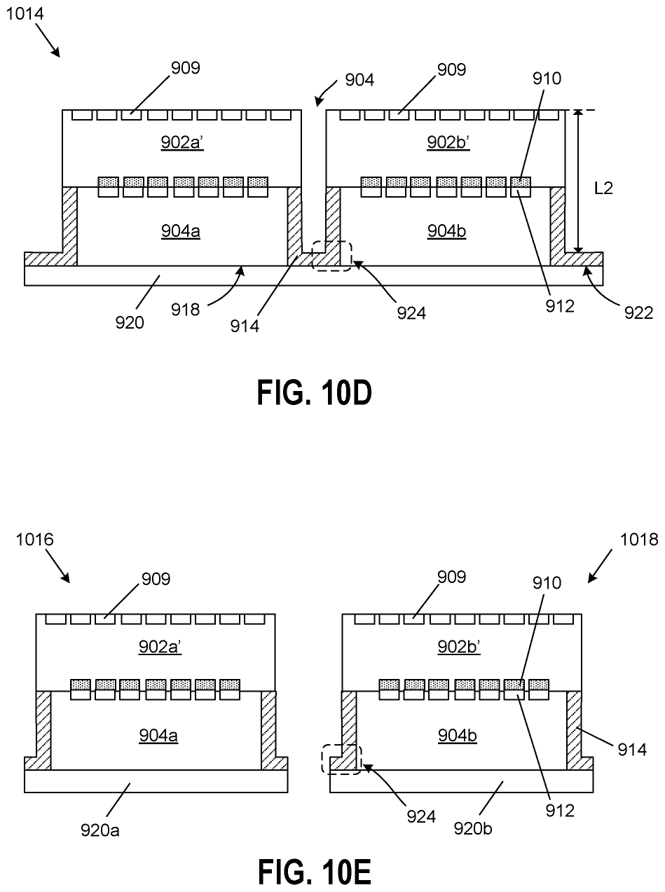

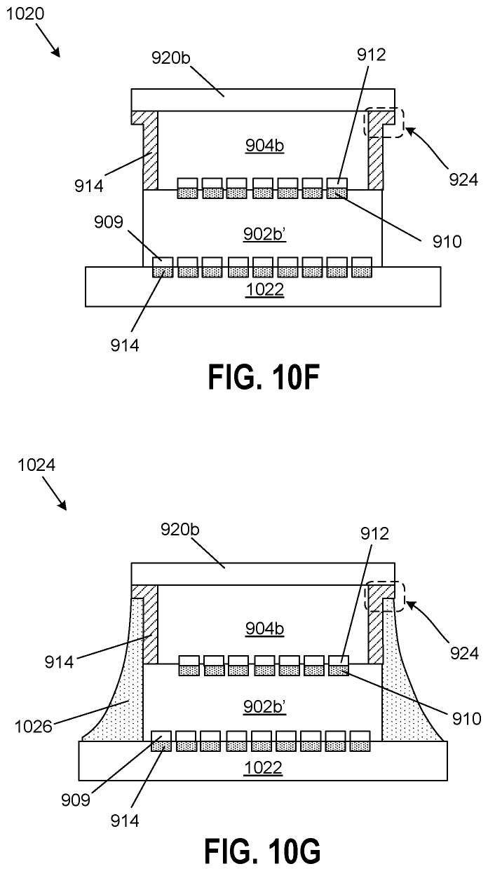

FIG. 10A illustrates a portion 1008 of microelectronic device wafer 900 after a process to form a mold structure has been performed on portion 908. As shown in FIG. 10A, mold material structure 914 is disposed on backside 916 of IC areas 902a, 902b between IC dies 904a, 904b. In some embodiments, mold structure 914 may be formed by flowing or depositing an appropriate molding compound over device wafer 900 and between IC dies 904. The process uses to form mold structure 914 may include overmold planarization operations that thins the mold material to create a flat surface 922 parallel to backsides 918 of IC dies 904. The processing and techniques for encasing integrated circuit device in a mold material layer are well known in the art and for purposes of clarity and conciseness are not discussed herein. Any suitable methods for known in the art for forming a mold structure may be employed. The molding compound used to form mold structure 914 may be any suitable an organic material or organic plastic material, such as an epoxy material. The molding compound may have a relatively low electrical conductivity, and may advantageously being a dielectric. Any alternative material known to be suitable for IC chip packaging applications may be used as a molding compound. In some exemplary embodiments, the molding compound comprises a cured (e.g., thermoset) resin or polymer comprising epoxy and/or silicone. The molding compound may also comprise a variety of fillers.

FIG. 10B illustrates a portion 1010 of microelectronic device wafer 900 after formation of a DBF 920 on portion 1008. As shown in FIG. 10B, DBF 920 is disposed on backsides 918 of IC dies 904a, 904b and on a side 922 of package mold structure 914. Although the composition of DBF 920 may vary, in embodiments, DBF may comprise Cu, Al, Ag, Au, diamond, or SiC. In various embodiments, DBF 920 has a thickness of 50 to 200 μm. In some embodiments, while DBF 920 may be formed using a deposition process, any suitable methods for known in the art for forming a DBF comprised of the aforementioned materials may be employed.

FIG. 10C illustrates a portion 1012 of microelectronic device wafer 900 after the wafer has been flipped. Portion 1012 is an inverted version of portion 1010.

FIG. 10D illustrates a portion 1014 of microelectronic device wafer 900 after the wafer has been cut to a first depth along scribe street 904 in a first step of a two-step singulation process. Portion 1014 corresponds with portion 1012 following the cutting operation. In the example of FIG. 10D, wafer 900 has been cut to a first depth L1 that singulates IC areas 902a, 902b into IC dies 902a′, 902b′. In an embodiment, the first depth L1 may be equal to the depth of IC areas 902a, 902b plus a portion of the depth of IC dies 904a, 904b. In embodiments, the cutting operation forms an overhang portion 924 in mold material structure 914. The cutting operation used to achieve portion 1014 may be any of the methods described in operations 204, 206 of method 200 or other methods known in the art for cutting wafer or mold material.

FIG. 10E illustrates portion 1014 of microelectronic device wafer 600 after wafer 900 has been cut to a second depth along scribe street 904 in a second step of a two-step singulation process. As shown in FIG. 10E, the cutting operation result in two portions 1016 and 1018. Cutting portion 1014 to the second depth cuts through remaining mold material and DBF 920, resulting in creation of DBF 920a and 920b. The cutting operation used to achieve portions 1016, 1018 may be any of the methods described in operations 204, 206 of method 200 or other methods known in the art for cutting metal material or mold material.

FIG. 10F illustrates portion 1020, which is portion 1018 after the portion has been flipped and then attached to substrate 1022. Portion 1018 may be mechanically attached and electrically coupled to substrate 1022 using any of the methods described in operation 208 of method 200 or other methods known in the art. Substrate 1022 may comprise conductive contacts 1024, which are in contact with conductive contacts 909 of IC die 902b′.

FIG. 10G illustrates portion 1024, which is portion 1020 after underfill 1026 is formed on the substrate 1022 in spaces under IC die 902b′, such as between bond pads of IC die 902b′, and in areas adjacent to the IC die 902b′. Underfill 1026 may be any of the materials described in operation 210 of method 200 or may be other materials. Underfill 1026 material may be applied using any of the techniques described in operation 210 of method 200 or may be applied using other means.

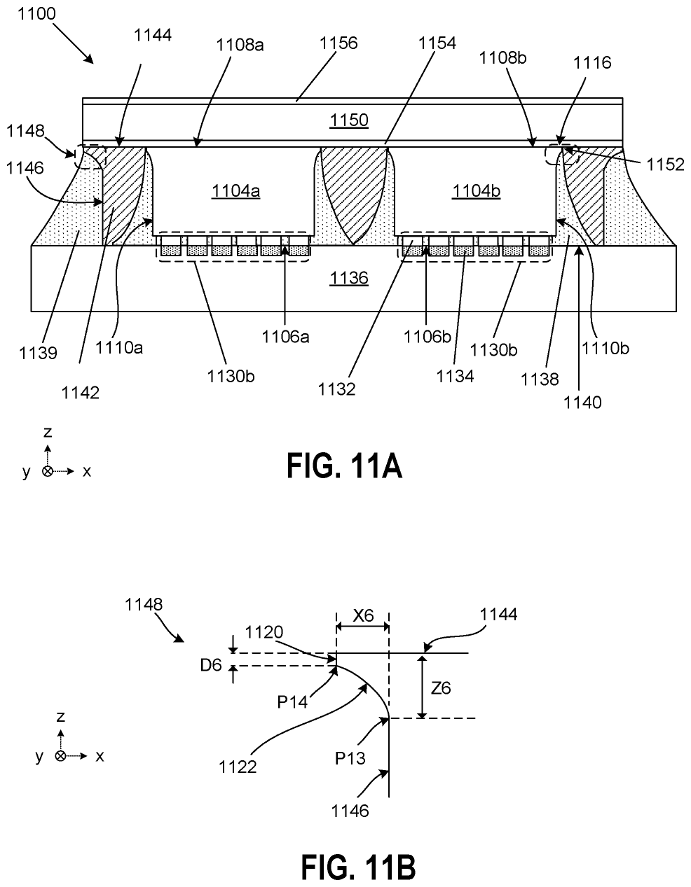

FIG. 11A is a cross-sectional side view of a device 1100 comprising a package mold structure, wherein the package mold structure comprises an overhang portion according to some embodiments. FIG. 11B is a cross-sectional side view of the overhang portion of the package mold structure of FIG. 11A according to some embodiments. The elements of FIGS. 11A-B are presented for illustration, and are not drawn to scale.

As shown in FIG. 11A, device 1100 comprises IC dies 1104a and 1104b (collectively “IC dies 1104”) mechanically attached and electrically connected to a substrate 1136. As further described below, a package mold structure 1142 is disposed on front side 1140 of substrate 1136 and around IC dies 1104a, 1104b, and a DBF 1150 is disposed on the mold structure 1142 and dies 1104. According to various embodiments, package mold structure 1142 comprises an overhang portion 1148, described below with reference to FIG. 11B. Device 1100 can include an adhesion layer 1154, a backside metal (BSM) layer 1156, or both layers 1154 and 1156. Adhesion layer 1154 can comprise Ti, Ni, V, Au, SiN, or combinations thereof. BSM layer 1156 can comprise Ti, Ni, V, Au, SiN, or combinations thereof.

IC dies 1104a, 1104b each comprise one or more device layers and one or more metallization layers. IC dies 1104a, 1104b also respectively comprise backsides 1108a and 1108b. Film 1150 is disposed on respective backsides 1108a, 1108b. As used herein, backsides 1108a, 1108b of IC dies 1104a, 1104b are at respective interfaces of portions IC dies 1104a, 1104b and DBF 1150, or at respective interfaces of portions IC dies 1104a, 1104b and adhesion layer 1154.

In various embodiments, an exterior surface of a main body structure of device 1100 comprises one or both backsides 1108a, 1108b. In embodiments, the main body structure comprises one or both IC dies 1104a and 1104b. In some embodiments, the main body structure can comprise DBF 1150, adhesion layer 1154, and BSM layer 1156.

IC dies 1104a, 1104b respectively comprise front sides 1106a and 1106b, which are opposite respective backsides 1108a, 1108b. IC dies 1104a, 1104b respectively comprise sidewalls 1110a, 1110b. In some embodiments, an exterior surface of a main body structure of device 1100 comprises sidewalls 1110a, 1110b. In addition, in embodiments, each of sidewalls 1110a, 1110b are substantially perpendicular to backsides 1108a, 1108b.

In some embodiments, a main body structure comprises one or both of IC dies 1104a, 1104b and an exterior surface of the main body structure comprises IC die overhang portion 1116. In some embodiments, IC dies 1114a, 1114b each comprise IC die overhang portions 1116, and DBF 1150 on a main body structure extend along respective overhang portions 1116. In embodiments, IC die overhang portion 1116 may be the same as overhang portion 116, 118, or 119 of device 100, as illustrated in FIGS. 1A-E. IC die overhang portion 1116 comprises a sidewall structure 1152, which is substantially perpendicular to the backside 1108a, 1108b of IC dies 1104a, 1104b. The sidewall structure 1152 of overhang portion 1116 may be the same as or similar to sidewall 120 of device 100, as illustrated in FIGS. 1B, 1D.

IC dies 1104a, 1104b respectively include hardware interfaces 1130a and 1130b. Each hardware interface comprises bond pads, metal pins, pads, microbumps, balls and/or other conductive contacts 1132 on IC die 1104, each of which are for coupling with a bond pad, metal pin, pad, microbump, ball and/or other conductive contact 1134 of another structure. In the shown example, device 1100 comprises a substrate 1136 (e.g., an interposer, a package substrate, a circuit board, another IC die, or the like) and substrate 1136 comprises conductive contacts 134.

In various embodiments, device 1100 comprises first underfill material 1138 disposed on a front side 1140 of substrate 1136, as well as around and on conductive contacts 1132. First underfill material 1138 is also disposed along and in contact with sidewalls 1110a, 1110b. First underfill material 1138 may comprise organic polymers and inorganic fillers. First underfill material 1138 may be any of the materials described in operation 210 of method 200 or may be other materials. First underfill material 1138 may be applied using any of the techniques described in operation 210 of method 200 or may be applied using other means.

In embodiments, DBF 1150 comprises a thermal dissipation material. In various embodiments, DBF 1150 may have a thickness of 50 to 200 μm. DBF 1150 may comprise any of the materials of film 114.

In various embodiments, mold structure 1142 may be formed on the front side 1140 of substrate 1136. Mold structure 1142 comprises a top surface 1144, which is opposite a surface of mold structure 1142 that contacts front side 1140 of substrate 1136. Mold structure 1142 may, in some embodiments, extend along and contact first underfill 1138. In some embodiments, mold structure 1142 may encapsulate one or both IC dies 1104a, 1104b. In embodiments, top surface 1144 of mold structure 1142 is coplanar with backsides 1108a, 1108b of IC dies 1104a, 1104b. The molding compound used to form mold structure 1142 can be the same as the molding compound used to form mold structure 914 or may be different. In embodiments, mold structure 1142 extends around a main body structure.

In various embodiments, mold structure 1142 has a footprint on substrate 1136. Referring back to FIG. 1D, like the footprint of the IC die on substrate 136, the footprint of mold structure 1142 on substrate 1136 can be defined by sidewall 1146 of mold structure 1142. In embodiments, mold structure 1142 comprises four sidewalls that define a footprint of the mold structure on a substrate. In various embodiments, one or more overhang portions of mold structure 1142, e.g., overhang portion 1148, each extend outside horizontally past the footprint of mold structure 1142 on substrate 1136; the overhang portions extend outside of the footprint of mold structure 1142 and laterally away from sidewalls of the mold structure, e.g., sidewall structure 1146.

In various embodiments, device 1100 comprises second underfill 1139, which may be formed on front side 1140 of substrate 1136 and along sidewalls of package mold structure 1142. Second underfill 1139 may be any of the materials described in operation 210 of method 200 or may be other materials. Underfill 1139 material may be applied using any of the techniques described in operation 210 of method 200 or may be applied using other means.

In various embodiments, mold structure 1142 has an exterior surface that comprises a sidewall 1146, which is substantially perpendicular to backsides 1108a, 1108b of IC dies 1104. In embodiments, sidewall 1146 is substantially perpendicular to top surface 1144 of mold structure 1142. In various embodiments, mold structure 1142 comprises an overhang portion 1148.

As shown in FIG. 11B, overhang portion 1148 adjoins sidewall structure 1146. In some embodiments, overhang portion 1148 comprises another sidewall structure 1120, which is substantially perpendicular to backsides 1108a, 1108b of IC dies 1104a, 1104b. In addition, sidewall structure 1120 may be substantially perpendicular to top surface 1144 of mold structure 1142. Sidewall structure 1120 may have a height of D6, which may be 1 to 3 μm in various embodiments. In some embodiments, overhang portion may not have a sidewall structure 1120 and the z-axis thickness of overhang portion 1120 is progressively reduced from a thickness of Z6 at point P13 until surface 1122 reaches a thin featheredge at a point on the top surface 1144 of mold structure 1142, wherein the point is a distance X6 of about 5 to 200 μm from sidewall 1146. Sidewall structure 1120 lies in a z-y plane (not shown), and, in some embodiments, sidewall structure 1120 may be spaced away from the plane in which sidewall structure 1146 lies by a distance X6 of 5 to 200 μm. In some embodiments, overhang portion 1148 extends laterally away from sidewall structure 1146 a distance X6 of 5 to 200 μm. In embodiments, overhang portion 1148 comprises a transitional surface 1122, which extends from point P13 of sidewall structure 1146 to point P14 of second sidewall structure 1120. In some embodiments, point P13 of sidewall structure 1120 is spaced away from top surface 1144 by a distance Z6 of 5 to 12 μm. In some embodiments, the point P14 of second sidewall structure 120 is outside of a footprint of mold structure 1142. In some embodiments, transitional surface 1122 may be, in cross section, an inward curving or concave surface having a radius of curvature of about 5 to 15 μm. In some embodiments, transitional surface 1122 may be a fillet. In some embodiments, transitional surface 1122 may be, in cross section, an irregular surface or a substantially linear surface, such as a bevel or chamfer. It will be appreciated that the geometry of transitional surface 1122 may vary with variations of a manufacturing process.

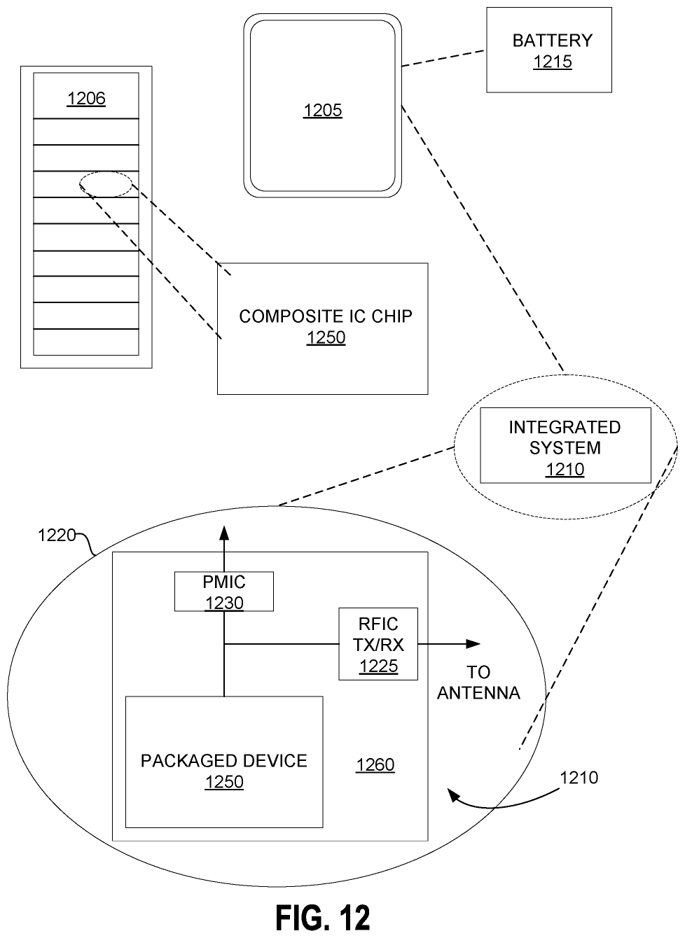

FIG. 12 illustrates a mobile computing platform 1205 and a data server machine 1206 employing a composite IC package 1250. In various embodiments, IC package 1250 comprises a device having an overhang portion, as described elsewhere herein. In some embodiments, a main body structure of the device comprises an IC die and an exterior surface of the main body structure comprises the overhang portion. The overhang portion adjoins a sidewall structure of the main body structure of the device, which is substantially perpendicular to a backside of the IC die. In some embodiments, the main body structure further comprises a package mold structure, which comprises the overhang portion, for example as described elsewhere herein. Server machine 1206 may be any commercial server, for example including any number of high-performance computing platforms disposed within a rack and networked together for electronic data processing, which in the exemplary embodiment includes a device having an overhang portion, as described elsewhere herein. In some embodiments, a main body structure of the device comprises an IC die and an exterior surface of the main body structure comprises the overhang portion. The overhang portion adjoins a sidewall structure of the main body structure of the device, which is substantially perpendicular to a backside of the IC die. In some embodiments, the main body structure further comprises a package mold structure, which comprises the overhang portion, for example as described elsewhere herein. The mobile computing platform 1205 may be any portable device configured for each of electronic data display, electronic data processing, wireless electronic data transmission, or the like. For example, the mobile computing platform 1205 may be any of a tablet, a smart phone, laptop computer, etc., and may include a display screen (e.g., a capacitive, inductive, resistive, or optical touchscreen), an integrated system 1210, and a battery 1215.

Whether disposed within the integrated system 1210 illustrated in the expanded view 1220, or as a stand-alone package within the server machine 1206, composite IC chip 1250 may include a device having an overhang portion, as described elsewhere herein. In some embodiments, a main body structure of the device comprises an IC die and an exterior surface of the main body structure comprises the overhang portion. The overhang portion adjoins a sidewall structure of the main body structure of the device, which is substantially perpendicular to a backside of the IC die. In some embodiments, the main body structure further comprises a package mold structure, which comprises the overhang portion, for example as described elsewhere herein. Composite IC chip 1250 may be further coupled to a host substrate 1260, along with, one or more of a host controller 1235, PMIC 1230, an RF (wireless) integrated circuit (RFIC) 1225 including a wideband RF (wireless) transmitter and/or receiver may be further coupled to host component 905. PMIC 1230 may perform battery power regulation, DC-to-DC conversion, etc., and so has an input coupled to battery 1215 and with an output providing a current supply to other functional modules. As further illustrated, in the exemplary embodiment, RFIC 1225 has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, and beyond.

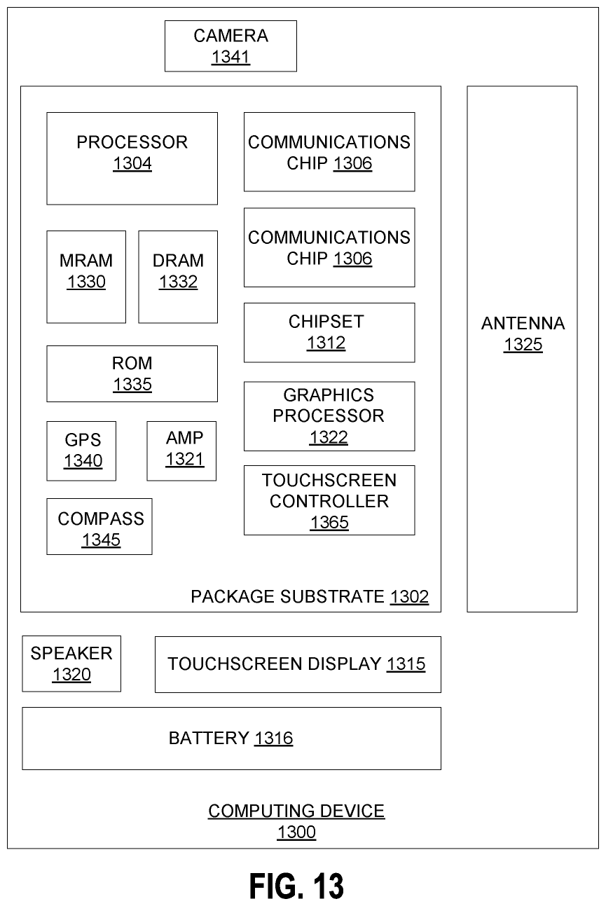

FIG. 13 is a functional block diagram of an electronic computing device 1300, in accordance with an embodiment of the present invention. Computing device 1300 may be found inside either mobile computing platform 1205 or server machine 1206, for example. Device 1300 further includes a package substrate 1302 hosting a number of components, such as, but not limited to, a processor 1304 (e.g., an applications processor). Processor 1304 may be physically and/or electrically coupled to package substrate 1302. In some examples, processor 1304 is within an IC die package or device having an overhang portion, for example as described elsewhere herein. In some embodiments, a main body structure of the package or device comprises an IC die and an exterior surface of the main body structure comprises the overhang portion. The overhang portion adjoins a sidewall structure of the main body structure of the IC die package or device, which is substantially perpendicular to a backside of the IC die. In some embodiments, the main body structure further comprises a package mold structure, which comprises the overhang portion, for example as described elsewhere herein. Processor 1304 may be implemented with circuitry in any or all of the IC die of the IC die package. In general, the term “processor” or “microprocessor” may refer to any device or portion of a device that processes electronic data from registers and/or memory to transform that electronic data into other electronic data that may be further stored in registers and/or memory.

In various examples, one or more communication chips 1306 may also be physically and/or electrically coupled to the package substrate 1302. In further implementations, communication chips 1306 may be part of processor 1304. Depending on its applications, computing device 1300 may include other components that may or may not be physically and electrically coupled to package substrate 1302. These other components include, but are not limited to, volatile memory (e.g., DRAM 1332), non-volatile memory (e.g., ROM 1335), flash memory (e.g., NAND or NOR), magnetic memory (MRAM 1330), a graphics processor 1322, a digital signal processor, a crypto processor, a chipset 1312, an antenna 1325, touchscreen display 1315, touchscreen controller 1365, battery 1316, audio codec, video codec, power amplifier 1321, global positioning system (GPS) device 1340, compass 1345, accelerometer, gyroscope, speaker 1320, camera 1341, and mass storage device (such as hard disk drive, solid-state drive (SSD), compact disk (CD), digital versatile disk (DVD), and so forth), or the like. In some exemplary embodiments, at least two of the functional blocks noted above are within a composite IC die package structure including a IC die bonded to two sides of an interposer, for example as described elsewhere herein. For example, processor 1304 be implemented with circuitry in an IC die on a first side of the interposer, and an electronic memory (e.g., MRAM 1330 or DRAM 1332) may be implemented with circuitry in an IC die on a second side of the interposer.

Communication chips 1306 may enable wireless communications for the transfer of data to and from the computing device 1300. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chips 1306 may implement any of a number of wireless standards or protocols. As discussed, computing device 1300 may include a plurality of communication chips 1306. For example, a first communication chip may be dedicated to shorter-range wireless communications, such as Wi-Fi and Bluetooth, and a second communication chip may be dedicated to longer-range wireless communications such as GPS, EDGE, GPRS, CDMA, WiMAX, LTE, Ev-DO, and others.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that the invention is not limited to the embodiments so described, but can be practiced with modification and alteration without departing from the scope of the appended claims. For example, the above embodiments may include specific combinations of features as further provided below.

The following examples pertain to further embodiments. Specifics in the examples may be used anywhere in one or more embodiments. All optional features of the apparatus described herein may also be implemented with respect to a method or process. The examples can be combined in any combinations. For example, example 4 can be combined with example 2.
Example 1: A device comprising: a main body structure comprising an integrated circuit (IC) die, wherein: an exterior surface of the main body structure comprises: a backside of the IC die; and a sidewall structure which is substantially perpendicular to the backside of the IC die; and an overhang portion of the main body structure adjoins the sidewall structure; and a film on the main body structure, the film comprising a thermal dissipation material, wherein the film extends along the overhang portion.
Example 2: The device of example 1, wherein the sidewall structure is a first sidewall structure, and wherein the overhang portion further comprises a second sidewall structure which is substantially perpendicular to the backside of the IC die.
Example 3: The device of example 1, wherein the IC die comprises the sidewall structure and the overhang portion.
Example 4: The device of example 3, wherein the sidewall structure is a first sidewall structure, and wherein the overhang portion is a first overhang portion, the device further comprising: a package mold structure which extends around the main body structure, wherein: an exterior surface of the package mold structure comprises a second sidewall structure which is substantially perpendicular to the backside of the IC die; and an overhang portion of the package mold structure adjoins the second sidewall structure.
Example 5: The device of example 1, wherein the main body structure further comprises a package mold which extends around the IC die, wherein the package mold comprises the sidewall structure and the overhang portion.
Example 6: The device of example 1, wherein the overhang portion of the main body structure comprises an inward curving transitional surface.
Example 7: The device of example 1, wherein a width of the overhang region is in a range of 5 microns to 200 microns, and a height of the overhang region is in a range of 5 microns to 12 microns.
Example 8: The device of example 1, wherein the film comprises one or more of Cu, Al, Ag, Au, diamond, SiC, or a ceramic material.
Example 9: The device of example 1, further comprising an underfill material which adjoins the sidewall structure.
Example 10: The device of example 9, wherein the underfill material comprises an organic polymer comprising one of bisphenol A resins, bisphenol F resins, or cycloaliphatic epoxy resins.
Example 11: A packaged device comprising: a substrate; a main body structure coupled to the substrate, the main body structure comprising an integrated circuit (IC) die, wherein: an exterior surface of the main body structure comprises: a sidewall structure; and an overhang portion adjoins the sidewall structure and extends outside horizontally past a footprint of the IC die on the substrate; and a film on the main body structure, the film comprising a thermal dissipation material, wherein the film extends along the overhang portion.
Example 12: The packaged device of example 11, wherein the IC die comprises the sidewall structure and the overhang portion.
Example 13: The packaged device of example 12, wherein the sidewall structure is a first sidewall structure, and wherein the overhang portion is a first overhang portion, the packaged device further comprising: a package mold structure which extends around the main body structure, wherein: an exterior surface of the package mold structure comprises: a second sidewall structure; and an overhang portion of the package mold structure adjoins the second sidewall structure and extends outside horizontally past a footprint of the package mold structure on the substrate; and a second film on the package mold structure, the second film comprising a thermal dissipation material, wherein the second film extends along the overhang portion of the package mold structure.
Example 14: The packaged device of example 11, wherein the main body structure further comprises a package mold which extends around the IC die, wherein the package mold comprises the sidewall structure and the overhang portion, and wherein the overhang portion extends outside horizontally past a footprint of the package mold on the substrate.
Example 15: The packaged device of example 11, wherein the overhang portion comprises a transitional surface having a radius of curvature in a range of 5 to 15 μm.
Example 16: The packaged device of example 11, a width of the overhang region is in a range of 5 microns to 200 microns, and a height of the overhang region is in a range of 5 microns to 12 microns.
Example 17: A system comprising: a packaged device comprising: a main body structure comprising an integrated circuit (IC) die, wherein: an exterior surface of the main body structure comprises: a backside of the IC die; and a sidewall structure which is substantially perpendicular to the backside of the IC die; and an overhang portion of the main body structure adjoins the sidewall structure; and a film on the main body structure, the film comprising a thermal dissipation material, wherein the film extends along the overhang portion; and a power supply to deliver power to the packaged device.
Example 18: The system of example 17, wherein the sidewall structure is a first sidewall structure, and wherein the overhang portion further comprises a second sidewall structure which is substantially perpendicular to the backside of the IC die.
Example 19: The system of example 17, wherein the IC die comprises the sidewall structure and the overhang portion.
Example 20: The system of example 17, wherein the main body structure further comprises a package mold which extends around the IC die, wherein the package mold comprises the sidewall structure and the overhang portion.

However, the above embodiments are not limited in this regard and, in various implementations, the above embodiments may include the undertaking of only a subset of such features, undertaking a different order of such features, undertaking a different combination of such features, and/or undertaking additional features than those features explicitly listed. The scope of the invention should therefore be determined with reference to the appended claims, along with the full scope of equivalents to which such claims are entitled.

What is claimed is:

1. A device comprising:
a main body structure comprising an integrated circuit (IC) die, wherein:
an exterior surface of the main body structure comprises:
a backside of the IC die; and
a sidewall structure which is substantially perpendicular to the backside of the IC die; and
an overhang portion of the main body structure adjoins the sidewall structure; and
a film on the main body structure, the film comprising a thermal dissipation material, wherein the film extends along the overhang portion.

2. The device of claim 1, wherein the sidewall structure is a first sidewall structure, and wherein the overhang portion further comprises a second sidewall structure which is substantially perpendicular to the backside of the IC die.

3. The device of claim 1, wherein the IC die comprises the sidewall structure and the overhang portion.

4. The device of claim 3, wherein the sidewall structure is a first sidewall structure, and wherein the overhang portion is a first overhang portion, the device further comprising:
a package mold structure which extends around the main body structure, wherein:
an exterior surface of the package mold structure comprises a second sidewall structure which is substantially perpendicular to the backside of the IC die; and
an overhang portion of the package mold structure adjoins the second sidewall structure.

5. The device of claim 1, wherein the main body structure further comprises a package mold which extends around the IC die, wherein the package mold comprises the sidewall structure and the overhang portion.

6. The device of claim 1, wherein the overhang portion of the main body structure comprises an inward curving transitional surface.

7. The device of claim 1, wherein a width of the overhang region is in a range of 5 microns to 200 microns, and a height of the overhang region is in a range of 5 microns to 12 microns.

8. The device of claim 1, wherein the film comprises one or more of Cu, Al, Ag, Au, diamond, SiC, or a ceramic material.

9. The device of claim 1, further comprising an underfill material which adjoins the sidewall structure.

10. The device of claim 9, wherein the underfill material comprises an organic polymer comprising one of bisphenol A resins, bisphenol F resins, or cycloaliphatic epoxy resins.

11. A packaged device comprising:
a substrate;
a main body structure coupled to the substrate, the main body structure comprising an integrated circuit (IC) die, wherein:
an exterior surface of the main body structure comprises:
a sidewall structure; and
an overhang portion adjoins the sidewall structure and extends outside horizontally past a footprint of the IC die on the substrate; and
a film on the main body structure, the film comprising a thermal dissipation material, wherein the film extends along the overhang portion.

12. The packaged device of claim 11, wherein the IC die comprises the sidewall structure and the overhang portion.

13. The packaged device of claim 12, wherein the sidewall structure is a first sidewall structure, and wherein the overhang portion is a first overhang portion, the packaged device further comprising:
a package mold structure which extends around the main body structure, wherein:
an exterior surface of the package mold structure comprises:
a second sidewall structure; and
an overhang portion of the package mold structure adjoins the second sidewall structure and extends outside horizontally past a footprint of the package mold structure on the substrate; and
a second film on the package mold structure, the second film comprising a thermal dissipation material, wherein the second film extends along the overhang portion of the package mold structure.

14. The packaged device of claim 11, wherein the main body structure further comprises a package mold which extends around the IC die, wherein the package mold comprises the sidewall structure and the overhang portion, and wherein the overhang portion extends outside horizontally past a footprint of the package mold on the substrate.

15. The packaged device of claim 11, wherein the overhang portion comprises a transitional surface having a radius of curvature in a range of 5 to 15 μm.

16. The packaged device of claim 11, wherein a width of the overhang region is in a range of 5 microns to 200 microns, and a height of the overhang region is in a range of 5 microns to 12 microns.

17. A system comprising:
a packaged device comprising:
a main body structure comprising an integrated circuit (IC) die, wherein:
an exterior surface of the main body structure comprises:
a backside of the IC die; and
a sidewall structure which is substantially perpendicular to the backside of the IC die; and
an overhang portion of the main body structure adjoins the sidewall structure; and
a film on the main body structure, the film comprising a thermal dissipation material, wherein the film extends along the overhang portion; and
a power supply to deliver power to the packaged device.

18. The system of claim 17, wherein the sidewall structure is a first sidewall structure, and wherein the overhang portion further comprises a second sidewall structure which is substantially perpendicular to the backside of the IC die.

19. The system of claim 17, wherein the IC die comprises the sidewall structure and the overhang portion.

20. The system of claim 17, wherein the main body structure further comprises a package mold which extends around the IC die, wherein the package mold comprises the sidewall structure and the overhang portion.
